(19) United States
(12) Patent Application Publication
(10) Pub. No.: US 2026/0087188 A1
(43) Pub. Date: Mar. 26, 2026

(54) SYSTEMS, METHODS, AND INTERFACES FOR BUILDING A REPRESENTATION OF A MIX DESIGN

(71) Applicant: ExeVision, Inc., South Jordan, UT (US)

(72) Inventors: Floyd Wilson Millet, South Jordan, UT (US); Phillip Timothy Daley, South Jordan, UT (US)

(21) Appl. No.: 19/332,791

(22) Filed: Sep. 18, 2025

Related U.S. Application Data
(60) Provisional application No. 63/697,299, filed on Sep. 20, 2024.

(51) Int. Cl. G06F 30/12; G06F 30/13

(52) U.S. Cl. CPC G06F 30/12; G06F 30/13

(57) ABSTRACT

Systems and methods are provided for constructing and executing a representation of a mix design. A mix design may be defined via user input specifying attributes, questions, calculations, variables, and tests. A structured data model representing the mix design may be constructed and executed to determine whether a sample mix corresponds to the mix design. Execution may include presenting a sample input interface, receiving sample mix input, performing calculations to determine variables, and testing the variables against compliance criteria. Bin-level questions and calculations may also be defined and executed. The representation may be used both to reproduce the mix design and to evaluate sample mixes.

### CROSS-REFERENCE TO RELATED APPLICATIONS

This application claims priority to U.S. Provisional patent application Ser. No. 63/697,299, filed on Sep. 20, 2024, and entitled “SYSTEMS, METHODS, AND INTERFACES FOR BUILDING A REPRESENTATION OF A MIX DESIGN”, the entirety of which is incorporated herein by reference for all purposes.

### BACKGROUND

Construction project managers use mix designs to provide a consistent material throughout a project. Mix designs act as a recipe that, if followed, will produce a mix designed material with the same desired characteristics every time. This consistency helps to ensure the quality and structural integrity materials in the project, whether they are concrete, asphalt, or other materials. By adhering to a well-defined mix design, project managers can minimize variability and improve consistency in the material properties.

Government agencies use mix designs to establish standards to be followed for a given project and a given material. In this way, they ensure that construction projects meet specific safety and performance criteria. These standards often mandate the use of certain mix designs for various applications, such as road construction, building foundations, and infrastructure projects. Standardized mix designs additionally simplify the review and approval process for new projects, as they provide a clear benchmark against which proposals can be evaluated. By standardizing mix designs, government agencies seek a baseline level of quality across different projects. This allows the agencies to facilitate regulatory compliance and ultimately to enhance public safety.

The subject matter described herein is not limited to embodiments that operate only in environments such as those described above. Rather, this background is only provided to illustrate one exemplary technology area where some embodiments described herein may be practiced.

### BRIEF DESCRIPTION OF THE DRAWINGS

In order to describe the manner in which the above recited and other advantages and features can be obtained, a more particular description briefly described above will be rendered by reference to specific examples thereof, which are illustrated in the appended drawings. Understanding that these drawings are merely illustrative and are not therefore to be considered to be limiting of its scope, embodiments described herein will be described and explained with additional specificity and detail through the use of the accompanying drawings in which:

FIG. 1 illustrates a user interface of a mix design panel associated with a method in accordance with one or more embodiments described herein.

FIG. 2 illustrates a user interface of a mix design panel including an attributes subpanel associated with a method in accordance with one or more embodiments described herein;

FIG. 3 illustrates a user interface of an add attribute subpanel associated with a method in accordance with one or more embodiments described herein;

FIG. 4 illustrates a user interface of a mix design panel including a variables subpanel associated with a method in accordance with one or more embodiments described herein;

FIG. 5 illustrates a user interface of an add variable subpanel associated with a method in accordance with one or more embodiments described herein;

FIG. 6 illustrates a user interface of a test panel including a test definitions panel associated with a method in accordance with one or more embodiments described herein;

FIG. 7 illustrates a user interface of an add question subpanel in a tests information subpanel associated with a method in accordance with one or more embodiments described herein;

FIG. 8 illustrates a user interface of an add calculation subpanel in a tests information subpanel associated with a method in accordance with one or more embodiments described herein;

FIG. 9 illustrates a user interface of a mix design panel including a test panel associated with a method in accordance with one or more embodiments described herein;

FIG. 10 illustrates a user interface of a test details subpanel associated with a method in accordance with one or more embodiments described herein;

FIG. 11 illustrates a user interface of an execute test subpanel associated with a method in accordance with one or more embodiments described herein;

FIG. 12 illustrates a user interface of a mix design panel including a batching subpanel and a questions subpanel associated with a method in accordance with one or more embodiments described herein;

FIG. 13 illustrates a user interface of a mix design panel including a batching subpanel and a calculations subpanel associated with a method in accordance with one or more embodiments described herein;

FIG. 14 illustrates a user interface of a mix design panel including a batching subpanel and a bin design subpanel associated with a method in accordance with one or more embodiments described herein.

FIG. 15 illustrates a user interface of a mix design panel including a batching subpanel and a bin calculations subpanel associated with a method in accordance with one or more embodiments described herein.

FIG. 16 illustrates an example flow diagram depicting one or more acts associated with the disclosed subject matter.

FIG. 17 conceptually depicts one or more components of a system that may include or implement the disclosed subject matter.

### DETAILED DESCRIPTION

Embodiments described herein provide systems, methods, and computer program products related to constructing a representation of a mix design.

A mix design, in the context of construction and materials testing, defines the composition and characteristics of a material mixture (e.g., concrete, asphalt, aggregate). Mix designs may be used to ensure consistency, quality, and compliance with project specifications or regulatory standards. A representation of a mix design as described herein may be constructed using a structured data model that captures user-defined attributes, questions, calculations, variables, tests, and/or bin-level configurations. This structured representation may be executed by a system to determine whether a sample mix corresponds to the defined mix design.

Constructing a representation of a mix design may include presenting a user interface that allows a user to define identifying information for the mix design and to associate it with one or more components. These components may include: attributes, which define static characteristics of the mix (e.g., binder grade, sieve percentages, material type); questions, which define prompts for user input during testing (e.g., batch weights, material readings); calculations, which transform question responses into derived values (e.g., air voids, oil content); variables, which represent measurable properties of the mix derived from calculations; tests, which define compliance criteria (e.g., pass/fail thresholds, acceptable ranges); batching configurations, which define bin-level compositions and allow for granular evaluation of mix components; and/or others.

The system may allow users to define these components through modular interfaces and associate them with either the mix design as a whole or with individual bins. For example, bin-level questions and calculations may be defined to evaluate specific portions of the mix (e.g., material retained on a particular sieve), while mix-level components may apply to the overall composition.

Once constructed, the representation of the mix design may be executed to validate whether a sample mix conforms to the defined design. During execution, the system may present the defined questions to a user, receive sample mix input, perform the associated calculations, and evaluate the resulting variables against the defined tests. This process may enable automated, structured, and repeatable validation of material samples, reducing reliance on manual spreadsheet-based workflows and improving traceability, reproducibility, and regulatory compliance.

In some implementations, the system may support the use of templates, versioning, and reuse of components across multiple mix designs. This facilitates efficient setup of new designs, supports collaboration between contractors and agencies, and enables consistent enforcement of material standards across projects.

In addition to validating sample mixes, representations of mix designs embodied as executable structured data models may be used to propose mix designs for use in construction projects. For example, a contractor or supplier may construct a representation of a proposed mix design and submit it to an agency or third party for review. Because the representation includes structured definitions of attributes, questions, calculations, variables, and tests, it may be executed by others to reproduce the mix and evaluate its suitability for a particular application. This may include running the defined tests on a recreated sample, comparing results to the embedded compliance criteria, and determining whether the proposed mix meets project specifications or regulatory standards. In some implementations, the representation may be used to facilitate approval workflows, inter-agency collaboration, or template generation for future reuse. As discussed in the disclosure meeting, this approach supports scalable, consistent, and auditable mix design management across diverse operational environments.

According to one implementation, a method may be computer implemented and can include presenting, on a user interface display, an input field for receiving identifying information for a mix design. The identifying information may include a given name for the mix design. The name may be the name of a template or generic mix design or a created mix design. For example, a template or generic mix design may be provided either by other users, contractors, or government agencies that meet certain requirements and standards. A created mix design may be a user-generated mix design that has custom characteristics and properties for a mix design for a given construction project.

The method can also include receiving user input that provides the identifying information for the mix design on a mix design panel. For example, the user may input a name of a mix design, and information relating to the mix design may be displayed on the user interface. For example, information relating to the mix design may include the name of the mix design, the effective date of the mix design, the expiration date of the mix design, the version of the mix design, and/or any tests associated with the mix design. The information may also include a Producer Mix ID, an Agency Mix ID, a Mix Design Type, and/or a material code.

The associated tests may be presented in the form of a drop down list such that upon a user selection of a selectable drop down element, a list of associated tests is displayed. The associated tests may be template tests or user-created tests. The tests may be used to determine if a given sample corresponds to the input mix design as will be described later. The effective and expiration dates presented may beneficially allow a user to ascertain whether the input mix design is still approved for use and/or when such approval expires.

The user interface may also present one or more user selectable elements along with the information relating to the mix design. The one or more user selectable elements may each provide an interface to different and/or similar characteristics and properties of the chosen mix design.

For example, one of the selectable elements may be an attributes selectable element. When the attributes selectable element is selected, an attributes subpanel may be displayed (e.g., on the user interface) that contains information and additional user selectable elements corresponding to attributes associated with the mix design. In one example, the attributes subpanel may include a user input element that enables a user to input an attribute. The attribute is then searched for within a list of attributes. The attributes in the list of attributes may be associated with the mix design, template attributes, and/or attributes created by a user. The attributes subpanel may also include one or more user selectable elements that allow the user to search attributes, add attributes, edit attributes, and/or delete attributes.

If a user selects the add attribute selectable element, an additional panel may be displayed on the screen that contains multiple fields into which the user may input details associated with the attribute to be added. For example, a user may input a name, choose a value from a source, or input a value for the attribute. In short, the add attribute selectable element can enable a user to add an attribute into the list of attributes displayed on the attributes subpanel and associate that attribute with one or more mix designs.

The attributes subpanel may also include a display of one or more attributes that are associated with the mix design. Each attribute in the display may be selectable by the user. Once selected, the attribute may be editable and/or deletable by means of the above described user selectable elements on the attributes subpanel. In short, the attributes subpanel can enable a user to view, edit, modify, delete, and search from attributes that could be attributes associated with the mix design, template attributes, or attributes created by the user.

Additionally, or alternatively, the attributes selectable element may enable a user to generate desirable attributes for the mix design or to incorporate previously generated generic or template attributes. For example, a user may desire that the mix design include a certain binder grade. After selecting the attributes selectable element, the user may input the desired binder grade and save it as part of the mix design. Additionally, the user may desire that the mix design include a generic or template attribute and may, after selecting the attributes element, import the desired generic or template attribute from a selected generic or template mix design. Accordingly, the method can include, after selection of an attributes selectable element, presenting one or more input fields for receiving attribute information, receiving user input from the one or more input fields, and generating an attribute based on the user input from the one or more input fields.

The attributes subpanel can thus enable a user to design, create, and delete attributes of a mix design and associate attributes with mix designs, and can use user input elements, user selectable elements, and presentations of information to accomplish such.

Another one of the selectable elements may be a variables selectable element. When the variables selectable element is selected, a variables subpanel may be presented (e.g., on the user interface) that contains information corresponding to one or more variables associated with the mix design as well as one or more user selectable variables subpanel elements. The variables subpanel may be similar to the attributes subpanel and may incorporate similar features applied to variables associated with the mix design instead of attributes. For example, the variables subpanel may include a user input element that enables a user to input a variable. The variable can then be searched for within a list of variables. The variables in the list of variables may be associated with the mix design, template variables, and/or variables created by a user. The variables subpanel may also include one or more user selectable elements that allow the user to search variables, add variables, edit variables, and/or delete variables.

If the user selects the add variable selectable element, an additional panel may be displayed on the screen that contains multiple fields into which the user may input details associated with the variable to be added. For example, a user may input a name, choose a value from a source, or input a value for the attribute. In short, the add attribute selectable element can enable a user to add an attribute into the list of attributes displayed on the attributes subpanel and associate that attribute with one or more mix designs

The variables subpanel may also include a display of one or more variables that are associated with the mix design. Each variable in the display may be selectable by the user. Once selected, the variables may be editable and/or deletable by means of the above described user selectable elements on the variables subpanel. In short, the variables subpanel enables a user to view, edit, modify, delete, and search from variables that could be variables associated with the mix design, template variables, or variables created by the user.

In some instances, the variables may have a value that corresponds to one or more executed samples. The tests performed on a real-world sample such as a crushing test may render the sample unusable for further testing. In such scenarios, multiple samples may be executed by the user and different tests may be conducted thereon. According to one implementation, the value of the variable can correspond to the appropriate test conducted on the sample. For example, if the variable is Air Voids, then the corresponding executed sample may yield an Air Voids value. As an additional example, a variable with a value corresponding to water content, then the corresponding executed sample may provide a water content value.

According to another implementation, the value of the variable may correspond to a test executed by the user and attached to the mix design. Such a test may be a test as described in further detail below. The test may be a template test, a user generated test, or a customized test that provides passing and failing values for a given property. The value of the variable may correspond to an answer to a question in the test.

Additionally, or alternatively, the variables selectable element may enable a user to generate desirable variables for the mix design or to incorporate previously generated generic or template variables. For example, a user may desire that the mix design include a certain value associated with the Air Voids of the mix design. The user may either input the desired value for the variable or may select to associate the value of the variable to the output of a test that is executed on a sample, as will be described in further detail below. Additionally, the variables may be machine setup variables or settings or other parameters that should be selected to accurately reproduce the mix design. As yet another example, the user may desire that the mix design include a generic or template variable and may, after selecting the variables element, import the desired generic or template variable from a selected generic or template mix design Accordingly, the method can include after selection of a variables selectable element, presenting one or more input fields for receiving variable information, receiving user input from the one or more input fields, and generating a variable based on the user input from the one or more input fields.

Yet another one of the selectable elements may be a tests selectable element. Upon selection, the tests selectable element may present (e.g., on the user interface) a tests subpanel that presents information and additional user selectable elements. The additional user selectable elements may enable a user to add, edit, execute, and/or delete a test. The tests subpanel may include similar features to the above described attributes and variables subpanels.

According to some embodiments, a test may be generated by a user. Generated tests may be stored in a library of tests. In at least such a way, the user may generate a library of tests that can be template tests for further customization and use in a mix design. For example, generating a test may include presenting (e.g., on the user interface) a user selectable element that, when selected, causes display of a panel on the user interface. The panel may include one or more additional user selectable elements that, when selected, allow a user input to modify an aspect of the test. For example, the user may input a name for the test, one or more questions for the test, one or more calculations for the test, one or more graphs for the test, one or more documents associated with the test, and/or other features for the test.

The tests selectable element may enable a user to generate a test or to incorporate a previously generated generic or template test in the mix design. The test may include one or more questions with one or more passing or a failing parameters corresponding to one or more properties. For example, the test may include a passing percentage by weight of a particular bin in a mix design. Additionally, the test may indicate how the test is to be performed (e.g., testing methods, crushing weights for a sample cylinder of an aggregate). Once executed, the test may produce results that can be incorporated into the mix design. For example, if the user has associated a variable to the results of an executed test, then, when the test is run, the corresponding result will be used to update the value of the variable. Accordingly, generating a variable based on the user input from the one or more input fields can include generating a variable that has a value that corresponds to a value that is generated upon the execution of a test.

Executing a test may include selecting an execute selectable element. When a test is executed, the questions and properties associated with the executed test (and/or input/query fields associated therewith) are presented to the user on a user interface display. The user may input answers to one or more of the presented questions. Some of the presented test properties may be directed towards test execution information such as who conducted the test, when the test was conducted, and if there are any documents associated with the test. The answers to each question in the test are input by the user. Any calculations associated with the questions are then executed to produce results for the test. The calculations can include comparing the user input value for a question with any passing parameters associated with the question and determining whether the input value is a passing value or not.

According to one implementation, the questions for the test can include questions about material properties of the test. Each question can have any kind of passing conditions, such as, by way of non-limiting example, a passing range with endpoints defined by a high passing value and a low passing value. For example, certain standards provided by the government for a project may include a passing range (e.g., defined by a high-passing and a low-passing value) for a certain material property of a mix design. If a value for the material property input by a user during execution of the test satisfies the passing range (e.g., is at or above the low-passing value and is at or below the high-passing value), then the material may be approved. Such functionality may be implemented, for example, to determine whether a mix under scrutiny corresponds to a target mix represented by a mix design for which a test was constructed.

Accordingly, the method can include after selection of a tests selectable element, presenting one or more input fields for receiving test information, receiving user input from the one or more input fields, and generating a test based on the user input from the one or more input fields.

An additional selectable element may be a batching selectable element. The batching selectable element may display, on the user interface, a batching subpanel that may enable a user to generate a bin definition for each bin associated with the mix design. The mix design may include one or more bins, each bin having its own definition. As an illustrative example, the mix design may include 30% of a first bin, 30% of a second bin, 30% of a third bin, and 10% of a fourth bin. Each of the first through the fourth bins may have additional properties and characteristics associated with it. In some instances, the properties and/or characteristics of the different bins of a mix design can be defined, at least in part, by using the attributes, variables, and/or tests that were generated as described above. The bin definitions can enable the construction of the mix design by defining attributes, variables, tests, calculations, and/or questions associated with the different components that form the mix represented by the mix design.

The batching subpanel may present on the user interface one or more selectable elements including a questions selectable element, a calculations selectable element, a bin design selectable element, and/or a bin calculations selectable element. The questions selectable element may enable a user to generate questions that include pass/fail values associated with the questions for a particular bin for the mix design. Questions generated through this may be different from the questions generated as described above in that the questions generated as described above may apply to a generic or a template mix design and the questions generated for a specific bin may be tailored to a specific component or composition of a mix. The component-specific questions may be entirely new (e.g., generated via user input after selection of the questions selectable element associated with the batching selectable element) or may be based on a template or generic mix design (as described above). The questions generated in association with the batching selectable element may nonetheless have similar properties and methods of generation as those described previously. Additionally, or alternatively, questions may be incorporated from the above-described generated questions from the generic or template mix designs through a user input that determines from which test the questions should be associated.

The calculations selectable element associated with batching (or batching subpanel presented by the batching selectable element) may be similar to the calculations element described previously, with the same distinction as described in the last paragraph that the calculations generated for a specific bin may be entirely new or may be based on a template or generic mix design that has associated generic or template calculations that were previously generated by a user.

The bin design selectable element may incorporate the questions and calculations described in the previous two paragraphs to generate a bin definition. The bin definition may include properties and characteristics that are defined by the questions. For example, the questions may include pass/fail rates for tests associated with a bin and may also include pass/fail rates for amounts by weight of given material. The questions may include information regarding what is necessary for a bin to match the bin definition in the mix design.

Accordingly, determining the bin definitions may include generating questions regarding the bin in the mix design, generating calculations for the bin in the mix design, and determining a bin definition based on the questions and calculations.

As described above, the method can include after selection of a batching selectable element, presenting one or more selectable elements selected from a questions element, a calculations element, a bin design element, and/or a bin calculations element, generating a bin definition, and combining one or more bin definitions to construct the representation of the mix design.

In one implementation, a user may wish to validate whether a mix corresponds to a representation of a mix design. In such an implementation, the user may take a sample of the mix and run it through a sieve. After running it through the sieve, the user may gather data regarding each bin of the sieve. The user may then input that data into a test (e.g., during execution of the test) that is associated with the representation of the mix design. The test may ask questions regarding the overall sample and/or the specific bins of the sieve, and the data gathered by the user through the sieve and bins may be used to answer these questions. The test may generate results that indicate whether the input data passes the test (i.e., whether the sample of the mix corresponds to or matches the target mix represented by the pre-created mix design).

For example, the user may input data as to the respective weights by percent of multiple bins, and if those weights match the passing parameters of the questions/tests for those bins, then the test may return a positive result. The questions may also include some room for error in calculating whether input data matches the passing parameter due to complications arising from real world implementations of representations of mix designs. At any rate, should the test return a passing result for all the input data, then the user can validate that the mix corresponds to the representation of the mix design and can proceed with the project. A failing result can indicate a lack of correspondence between the mix being subjected to testing and the target mix represented by the mix design. In such a way, the tests, questions, calculations, and bin designs in accordance with the present disclosure can allow a user to quickly, effectively, and in a user-friendly manner determine if a mix is suitable for a project.

In at least one implementation, an individual may want to propose a mix design to be used for a given project. In such a case, the individual may use at least one implementation of the workflow in accordance with the present disclosure to build a representation of the mix design. For example, the individual may use a template to build a representation of a mix design or may build the representation of the mix design from scratch. If a template is used, the workflow may include presenting, on a user interface display, one or more selectable templates. The template may include information, properties, characterizations, and calculations of a template mix design. The template mix design may be provided by a contractor database or government agency or may be an otherwise previously accepted mix design. The workflow may also include receiving user input directed to the one or more selectable templates such that the user selects a desired template.

The workflow additionally may include, after receiving the user input directed to the selectable templates, presenting the user with additional selectable elements that, when selected, offer the ability to customize the selected template. For example, the user may be presented with the ability to add questions and/or calculations to the selected template, and/or modify tests and/or pass/fail parameters associated with tests that define characteristics of or for the mix design (and/or specific bins of the mix design). After receiving the user input directed to the one or more additional selectable elements, a representation of a mix design may be constructed, which may be regarded as a definition of the mix design and/or a means by which a subject mix may be tested to determine whether the subject mix corresponds to the mix design. For instance, when a test of the mix design is executed (e.g., a bin-specific test and/or an overall test of the mix design), one or more user input prompts may be presented, and user input received via the prompt(s) is/are checked against the passing parameter(s) of each question defined by the mix design. According to whether the user input meets the passing parameter(s), a pass or fail result is generated for the user input. The pass or fail result may allow a user to know whether the sample with which the input data is associated corresponds to the mix design against which the sample is being checked.

In such a way, the test may define a mix design in that it may include the pass and fail parameters for properties of the mix design (and/or for each bin in the mix design). The test may be used to check whether a sample includes the mix design by a user inputting data about that sample and then checking the inputted data against the pass/fail parameter(s) for each property of the mix design (e.g., by executing one or more test of the stored mix design). Accordingly, the user may know whether a sample comprises a given mix design or not.

The built representation of the mix design may act as a definition or a recipe that, when implemented in the real world, can be used to produce a mix design with the same characteristics and qualities every time. For instance, using the variables and/or attributes represented in the mix design for the mix overall and/or the bins of the mix, a user can configure one or more mixing components (e.g., mixers, batching plants, pugmills, conveyors, hoppers, silos, water meters, dispensers, associated control systems, etc.) to create a mix. The mix can subsequently be tested using the overall and/or bin-specific tests and/or questions defined by the mix design to determine whether the created mix corresponds to the mix represented by the mix design. In at least such a way, implementations of the workflow in accordance with the present disclosure allow a quick, efficient, and user-friendly construction of a mix design that can be sent between parties for testing and approving of a mix design.

In an additional or alternative implementation, the workflow may include presenting on a user interface display one or more selectable elements. The selectable elements may include a plurality of buttons on a plurality of organizing tabs, each organizing tab having its own features and each button having its own corresponding action. For example, one organizing tab may be a test setup tab. The test setup tab may include a plurality of buttons, a plurality of fillable text boxes, and a presentation of one or more questions associated with a selected test. The test setup tab may allow a user to create and customize a new and/or a selected test in a workflow by adding, removing, copying, pasting, deleting, or editing questions associated with the new and/or selected test. The workflow may additionally include adding calculations associated with the test such that the answers to the questions may be used in the calculations. In the workflow, the calculations, when executed in a runtime environment, may receive the answers to the questions in the form of input from a user, perform mathematical operations thereon, and produce a result. The user may provide the input based on a real-world mix, such as to test whether a real-world mix corresponds to a target mix represented by a mix design. The workflow may include using the result of the calculations to determine whether the real-world mix corresponds to the target mix. In at least such a way, the workflow may include adding both questions and calculations in a test that can be used to assess whether a real-world mix corresponds to a target mix represented by a mix design.

In some implementations, the workflow may include building a representation of a mix design by generating a bin design for one or more bins associated with the mix design. The workflow may include presenting, on a user interface display, one or more selectable elements and receiving user input directed to the one or more selected elements. After receiving the user input directed to the one or more selectable elements, the workflow may include generating a bin design that includes one or more bins in a workflow that, when executed in a runtime environment, performs calculations on the user input and generates results for each bin in the bin design. Each bin in the bin design corresponds to a proportion of a given material in the mix design. For example, the mix design may include 30% of a first bin, 30% of a second bin, 30% of a third bin, and 10% of a fourth bin. In such a way, the workflow builds a representation of a mix design by receiving user input and using that input to generate the proportions of each bin in the bin design of the mix design.

In some implementations, the workflow may be executed to determine whether a sample of a material matches a mix design of the workflow. Such implementations may beneficially allow a fast and efficient approval process for a given material and/or may enable a user to accurately produce the mix represented by the mix design in the real world. In such implementations, use of the workflow may include retrieving a sample material from a geographical location and then sieving the sample material into one or more bins. After sieving, the one or more bins may indicate measurement data as to the proportions of one or more materials within the sample. The measurement data associated with each bin may be input into the workflow that, when executed in a runtime environment, performs calculations on the measurement data and determines whether the sample material on which the measurement data is based matches a mix design associated with the workflow. The mix design associated with the workflow may be a representation of a mix design built by any of the previously discussed workflows.

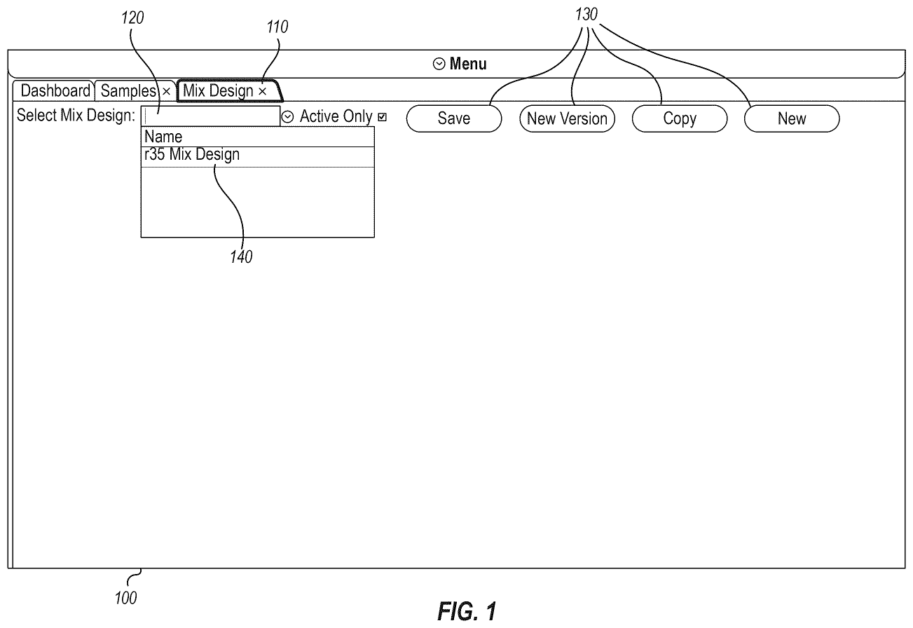

FIG. 1 illustrates a user interface 100 showing a mix design panel 110 associated with a method in accordance with one or more embodiments described herein. As shown in FIG. 1, the method may include presenting, on the user interface 100, a mix design panel 110 that enables a user to initiate the creation or modification of a mix design. The mix design panel 110 may include an input field 120 for receiving identifying information about a mix design, such as a name, code, or version identifier. For example, a user may input the name of a new mix design into the input field 120, or select an existing mix design from a list 140 of previously created mix designs displayed on the interface.

The list 140 may include selectable entries corresponding to existing mix designs, each of which may be associated with metadata such as effective date, expiration date, version number, or agency approval status. Upon selection of an existing mix design or entry of a new one, the system may retrieve and display associated information and present additional user interface elements for constructing or modifying a representation of the mix design. These additional elements may include selectable panels or subpanels for defining attributes, variables, tests, batching configurations, and other components of the mix design, as described in further detail below.

FIG. 1 also shows that the one or more user selectable elements 130 may enable a user to perform actions such as saving a mix design, creating a new version of a mix design, copying a mix design, or generating a new mix design from scratch. These actions may initiate workflows that allow the user to define or refine the structure and logic of the mix design, including associating it with test templates, defining pass/fail criteria, and configuring bin-level components. In some implementations, the system may also allow users to import mix designs from templates or external sources, or to export mix designs for review, approval, or reuse.

User interface 100 may support real-world workflows in which users (e.g., contractors, agencies, or lab technicians) define and manage mix designs for use in construction projects. The ability to select from existing designs or create new ones provides flexibility for adapting to different materials, specifications, and regulatory requirements. The mix design panel 110 may thus serves as the entry point for constructing a structured data model that represents the mix design and can be executed to determine whether a sample mix corresponds to the defined design.

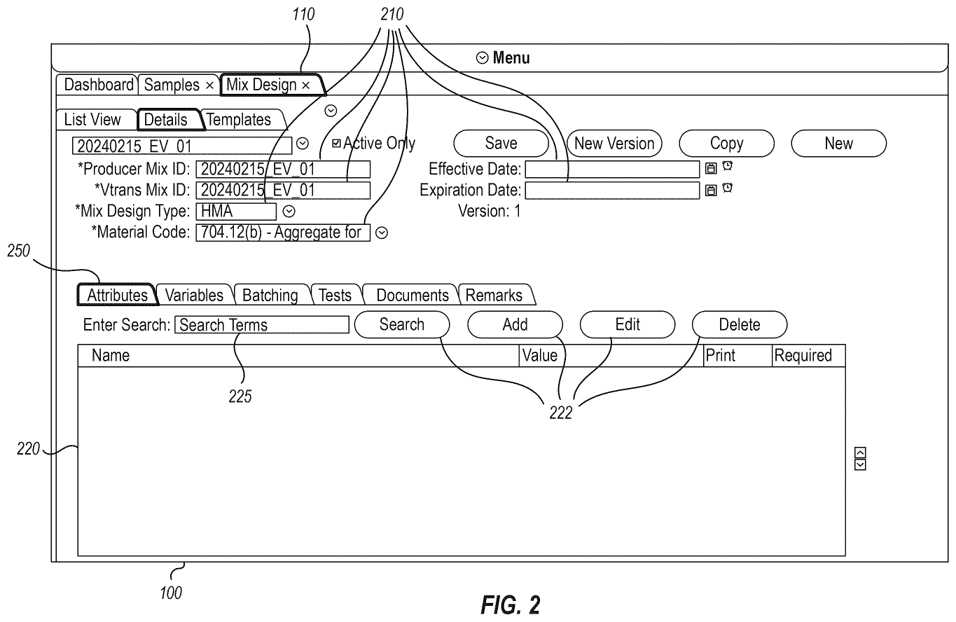

FIG. 2 illustrates a user interface 100 showing a mix design panel 110 including an attributes subpanel 220 associated with a method in accordance with one or more embodiments described herein. As shown in in FIG. 2, the method may include presenting, on the user interface 100, one or more mix details input fields 210. The one or more mix details input fields 210 may allow a user to input identifying information about a mix design. For example, the user may input a producer mix ID, an Agency Mix ID, a Mix Design Type, a material code, an effective date, and an expiration date. Additionally, or alternatively, the input fields may display a corresponding value for a property associated with the input field.

FIG. 2 also shows that the user interface 100 may include an attributes subpanel 220 (or a mix design attribute interface). The attributes subpanel 220 may be presented after selection of an attributes selectable element 250 and may include an attributes search input field 225 and one or more attributes subpanel selectable elements 222. The attributes search input field 225 may enable a user to input a name of an attribute to be searched. The one or more attributes subpanel selectable elements 222 may enable a user to search for an attribute, add an attribute, edit an attribute, and/or delete an attribute. Each attribute may have an associated value with that attribute.

An attribute of the mix design may comprise a definable characteristic of the mix composition or other physical or chemical properties relevant to the mix. Attributes may be defined at the mix level (e.g., overall characteristics of the mix design) or at the bin level (e.g., characteristics specific to a portion of the mix composition). In some implementations, attributes may be stored in a shared pool and selectively associated with either the mix design as a whole or with individual bins during batching. Example attributes include, but are not limited to: material type (e.g., aggregate, binder, admixture), sieve percentage (e.g., percent retained on a ¾″ sieve), binder grade (e.g., PG 64-22, PG 76-28), admixture source or type, cementitious content, and/or others.

The mix design attribute interface may present one or more input fields for defining such attributes, including dropdowns, text fields, selection menus, etc. Upon receiving user input, the system may store the attribute in association with the mix design and optionally allow reuse across other mix designs or bins.

In some implementations, attributes may be defined at the mix level to describe overall characteristics of the mix design, such as binder grade or total cementitious content. In other implementations, attributes may be defined at the bin level to describe characteristics of individual components of the mix, such as sieve percentages or material type for a specific bin. The system may allow attributes to be ported from a shared pool to either level, and may further allow refinement or customization of attributes depending on the context of use.

For example, a user may define a binder grade attribute at the mix level, and later associate that same attribute with a specific bin during batching. Similarly, sieve percentage attributes may be defined per bin to reflect the expected composition of aggregate materials passing through different sieve sizes. These attributes may be used to construct a representation of the mix design that ensures reproducibility and compliance with project specifications.

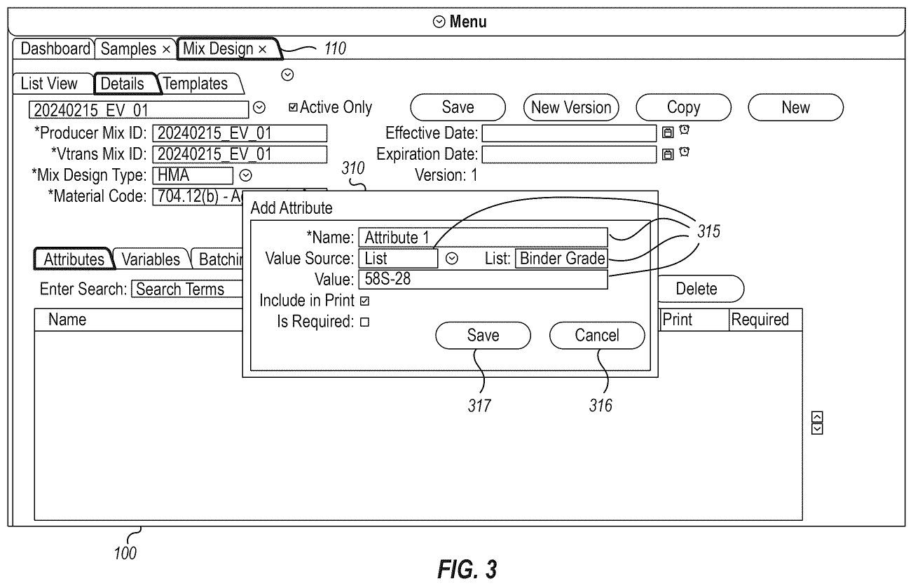

FIG. 3 illustrates a user interface 100 showing an add attribute subpanel 310 (or mix design attribute interface) associated with a method in accordance with one or more embodiments described herein. As shown in FIG. 3, when the user selects one of the attributes subpanel selectable elements 222 that is associated with adding an attribute (described with reference to FIG. 2), the method may include displaying, on the user interface 100, an add attribute subpanel 310. The add attribute subpanel 310 may include one or more add attribute user input fields 315 for receiving information corresponding to an attribute to be added. Once the user inputs information into the add attribute user input fields 315, the user may select a save selectable element 317 or a cancel selectable element 316. If the user selects the save selectable element 317, then a new attribute is saved and/or generated using the information entered by the user in the one or more add attribute user input fields 315. If the user selects the cancel selectable element 316, then a new attribute is not saved. Accordingly, the method can include displaying, on the user interface display, one or more user input fields for receiving information corresponding to an attribute to be added, and then adding, saving, and/or generating the corresponding attribute.

Additionally, the method may include after selection of an attributes selectable element, presenting one or more input fields for receiving attribute information, receiving user input from the one or more input fields, and generating an attribute based on the user input from the one or more input fields.

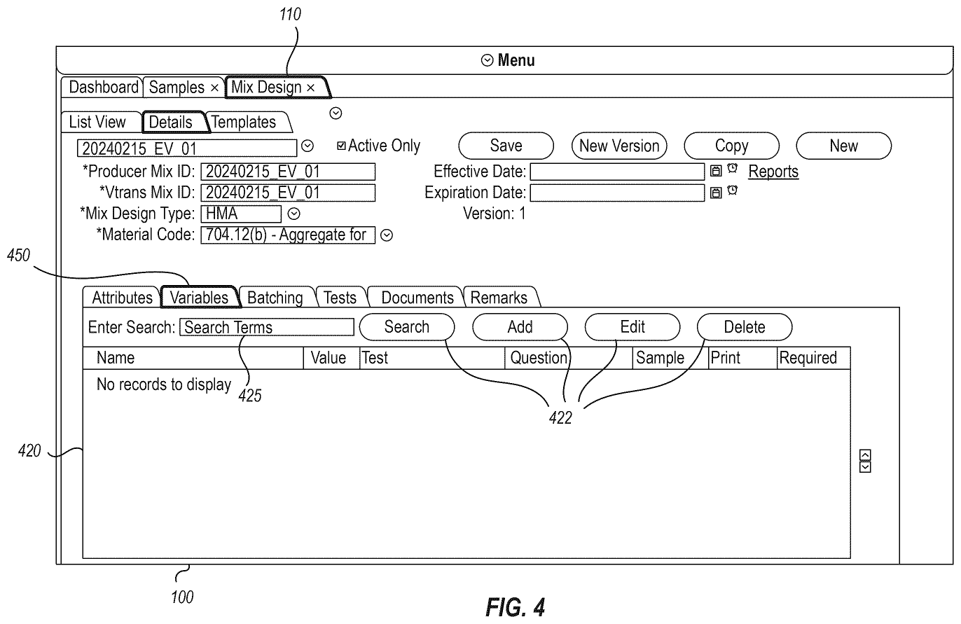

FIG. 4 illustrates a user interface 100 showing a mix design panel 110 including a variables subpanel associated with a method in accordance with one or more embodiments described herein. As shown in FIG. 4, the method may include presenting, on the user interface 100, a variables subpanel 420. The variables subpanel 420 may be presented after selection of a variables selectable element 450 and may include a variables search input field 425 and one or more variables subpanel selectable elements 422 that may be similar to the one or more attributes subpanel selectable elements 222. The variables search input field 425 may enable a user to input a name of a variable to be searched. The one or more variables subpanel selectable elements 422 may enable a user to search for a variable, add a variable, edit a variable, and/or delete a variable. Example variables that can be searched, added, or edited in association with a mix design include Air Voids, Binder Correction Factor, IOCF for AC Content per T 308, Mass of Mix, Project Constant, various Sieve % Retained variables, and/or others.

A variable of the mix design may comprise a computed value derived from user input in response to one or more questions. The value of the variable may be indicative of a measurable property of the mix, such as air voids, oil content, binder correction factor, and/or others. Variables may be used to assess whether a sample mix corresponds to a target mix design by comparing the computed values to expected values or ranges defined in the mix design representation (e.g., indicated via tests of the mix design representation).

Variables may be defined at different levels of granularity. Mix-level variables may represent properties of the overall mix design, while bin-level variables may represent properties specific to individual bins or components of the mix. In some implementations, variables may be stored in a shared pool and ported to either the mix level or bin level depending on the context. For example, a variable initially defined at the mix level (e.g., total binder content) may later be refined or reused at the bin level (e.g., binder content per sieve fraction).

The variables subpanel may allow users to define, edit, and associate variables with calculations, questions, or tests. Each variable may be linked to one or more calculations that determine its value based on user input received during execution of a representation of a mix design (e.g., via one or more tests of the mix design representation).

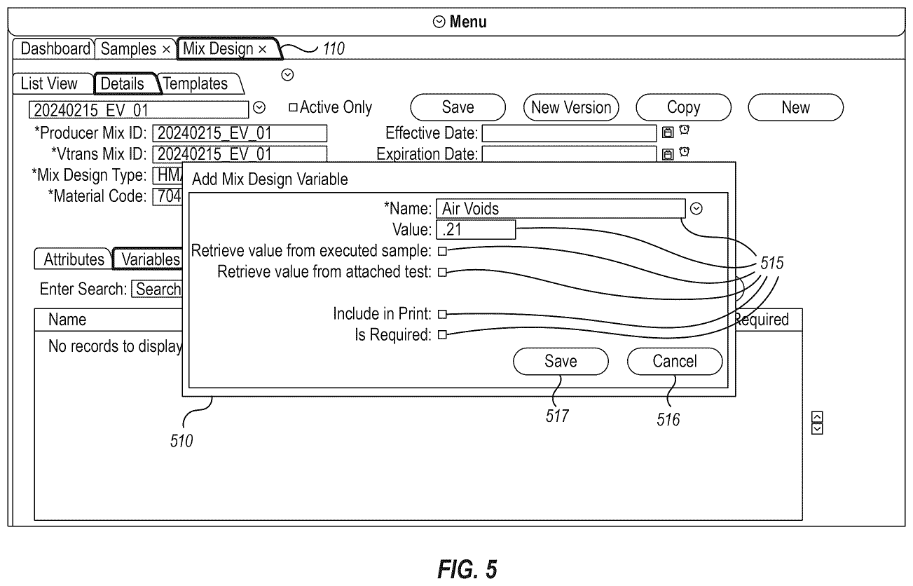

FIG. 5 illustrates a user interface 100 showing an add variable subpanel 510 associated with a method in accordance with one or more embodiments described herein. As shown in FIG. 5, when the user selects one of the variables subpanel selectable elements 422 that is associated with adding a variable, the method may include displaying, on the user interface 100, an add variable subpanel 510. The add variable subpanel 510 may include one or more add variable user input fields 515 for receiving information corresponding to a variable to be added. Once the user inputs information into the add variable user input fields 515, the user may select a save selectable element 517 or a cancel selectable element 516. If the user selects the save selectable element 517, then a new variable is saved and/or generated using the information entered by the user in the one or more add attribute user input fields 315. If the user selects the cancel selectable element 516, then a new variable is not saved.

Accordingly, the method may include after selection of a variables selectable element, presenting one or more input fields for receiving variable information, receiving user input from the one or more input fields, and generating a variable based on the user input from the one or more input fields;

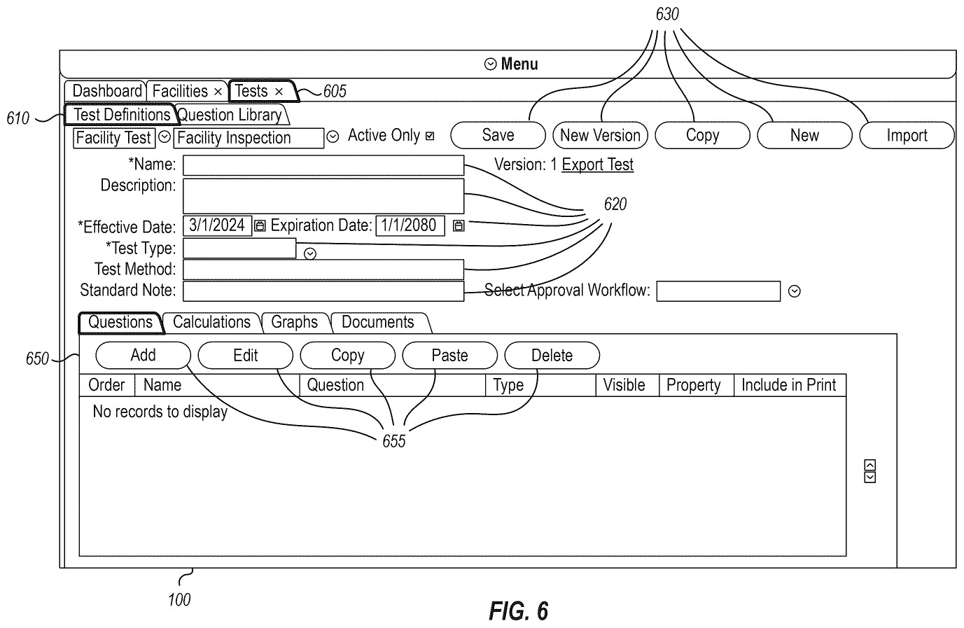

FIG. 6 illustrates a user interface 100 showing a test panel 605 (or mix design test interface) including a tests information subpanel 610 associated with a method in accordance with one or more embodiments described herein. As shown in FIG. 6, the method can include displaying, on the user interface 100, a tests information subpanel 610. The tests information subpanel 610 may include one or more tests information subpanel user input fields 620 and one or more tests information subpanel selectable elements 630. The tests information subpanel 610 may enable a user to view, edit, save, load, delete, import, copy, and/or create new versions of tests. The tests may be tests that become associated with one or more mix designs.

FIG. 6 also shows that the tests information subpanel 610 may include a questions subpanel 650 (or mix design question interface) that may enable a user to add, edit, copy, paste, and/or delete questions from one or more tests through one or more user selectable elements 655. For example, a user may input information about a test into the one or more tests information subpanel user input fields 620 and view questions associated with the corresponding test. The user, through the questions subpanel 650, may then add, edit, copy, paste, and/or delete questions associated with the test.

The mix design question interface may be presented via a tests information subpanel, which may enable a user to define one or more questions for association with a mix design. Each question may comprise one or more prompts configured to elicit user input during execution of a mix design representation. The user input received in response to these prompts may be used to determine sample mix data, such as material properties, composition percentages, or other measurable characteristics of a sample mix.

A question may comprise a prompt or query to be presented to a user during execution of a mix design representation, and may be configured to elicit input that can be used to assess whether a sample mix corresponds to the mix design. Questions may include prompts such as “Enter clay reading,” “Enter sand reading,” or “Enter the batch weight for the 3-inch sieve” (and/or other sieve sizes). Questions may be defined in the abstract (e.g., as part of a test template) and later incorporated into a specific mix design. The system may allow users to define questions using various input types, such as short answer (e.g., numeric or text input), calculation result (e.g., derived from other question responses), linked sample (e.g., pulling values from previously executed tests or sample data), multiple choice, list selection, lookup table inputs, and/or others. These questions may be stored in a question library and reused across multiple mix designs or bins.

The mix design test interface may be presented via a tests information subpanel, which may enable a user to define one or more tests for association with a mix design. A test, as used herein, may comprise a structured set of evaluation criteria configured to determine whether a sample mix corresponds to a target mix design. Tests may include one or more of: questions (e.g., prompts for user input such as batch weights or material readings), calculations (e.g., formulas that derive variables from question responses), graphs (e.g., visualizations of input or output data), documents (e.g., specifications, certifications, or supporting materials), and/or others.

Tests defined via the tests information subpanel may be stored as test templates, which can later be incorporated into specific mix designs. These templates may include reusable components such as question formats, calculation logic, and expected output structures. The system may allow users to define tests in the abstract and later refine them when associating the test with a particular mix design.

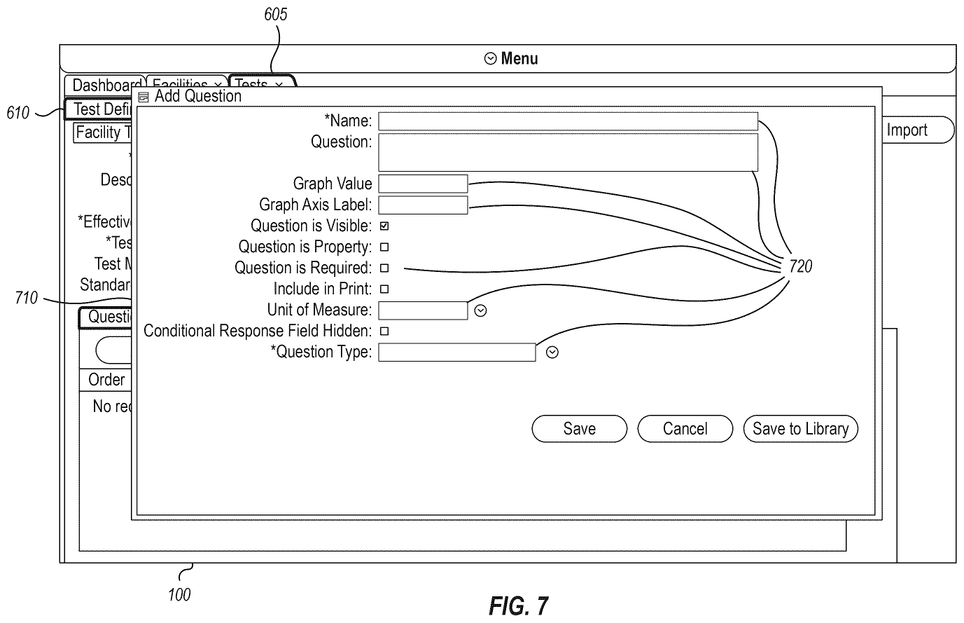

FIG. 7 illustrates a user interface 100 showing an add question subpanel 710 (or mix design question interface) in a tests information subpanel 610 associated with a method in accordance with one or more embodiments described herein. As shown in FIG. 7, the method may include presenting, on the user interface 100, an add question subpanel 710 that may include one or more add question subpanel user input fields 720 that enable a user to input information about a question to be added. The add question subpanel user input fields 720 can take on various forms, such as text input fields for indicating the name of the question and/or the content of the question, graph-related input such as graph values and axis labels (e.g., where the question prompts users to input information to be populated in a graph), selectable elements that indicate whether the question relates to a material property or whether an answer to the question is required or whether the question is to be visible and/or included in a report or other output/print, drop-down menus for selecting units of measure or question type, etc. The question may be saved, canceled, or saved to library. Accordingly, the method may include receiving information from a user relating to one or more questions and generating a question based on the user input information. The method may also include saving the one or more questions in a question library and associating the one or more questions with a test that is associated with a mix design.

The add question subpanel may serve as the mix design question interface, allowing users to define the content, format, and behavior of each question. Each question may include metadata such as units of measure, required status, visibility, and whether the question is included in printed reports. The system may also allow the user to specify whether the question is associated with a particular material property, bin, or mix-level attribute.

Questions may be associated with one or more calculations, which may transform the user input (e.g., provided in answer to the questions) into derived values (e.g., air voids, binder correction factor) which may be used to assess whether a sample mix corresponds to the mix design. In some cases, questions may be linked to specific bins or components of the mix design, allowing for granular evaluation of sample mix data. For example, a question may prompt the user to enter the batch weight for a specific sieve size, and a corresponding calculation may indicate the percentage retained or the compliance with a target range.

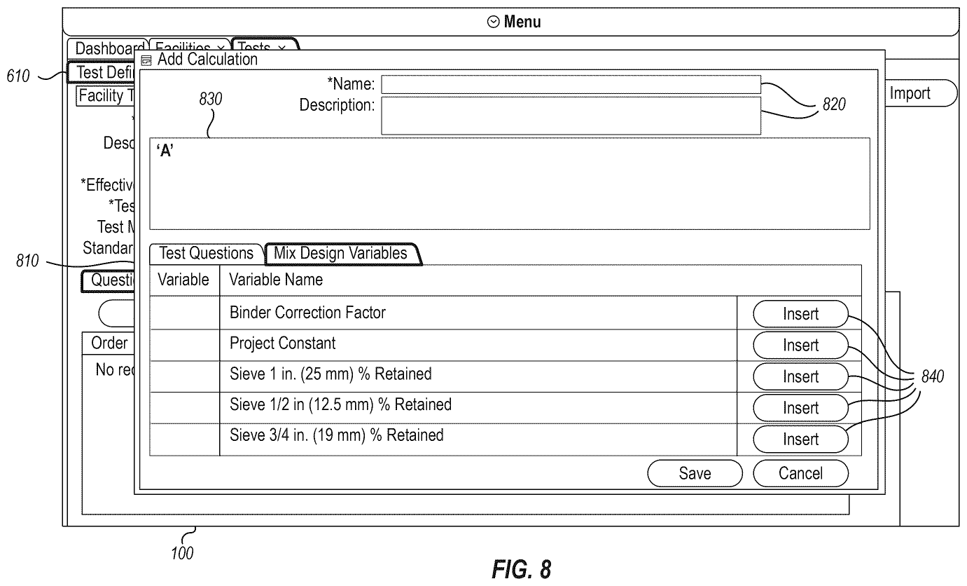

FIG. 8 illustrates a user interface 100 showing an add calculation subpanel 810 (or mix design calculation interface) in a tests information subpanel 610 associated with a method in accordance with one or more embodiments described herein. As shown in FIG. 8, the method may include presenting, on the user interface 100, an add calculation subpanel 810 that may include one or more add calculation subpanel user input fields 820 that enable a user to input information about a calculation to be added. The calculation 830 may be saved, canceled, or saved to library. The calculation 830 may be associated with one or more questions and/or tests that is associated with a mix design.

Additionally, or alternatively, the calculation 830 may correspond to the values of one or more mix design variables 840. The calculation 830 may thus be utilized in conjunction with an executed test and/or may be used to update and/or determine the value of the corresponding mix design variable 840. Accordingly, the method may include receiving information from a user relating to one or more calculations and correlating the calculation 830 to a test question, a mix design variable, or both based on the user input information. The method may also include saving the calculation 830 in a calculation library.

Accordingly, the method may include after selection of a tests selectable element, presenting one or more input fields for receiving test information, receiving user input from the one or more input fields, and generating a test based on the user input from the one or more input fields.

A calculation, as used herein, may comprise a formula, expression, or logic operation that transforms user input (e.g., responses to questions) into a derived value. Calculations may be used to process inputs received via prompts to generate outputs that are usable to determine whether a sample mix matches or sufficiently corresponds to a mix design. For example, a calculation may determine air voids based on input sample mass and volume, or compute oil content based on input binder weight and total mix weight.

Calculations may be defined using any desired syntax and may reference one or more questions, variables, or constants. The mix design calculation interface may allow users to define calculations through an add calculation subpanel, where they can specify the formula, input dependencies, and output variable. Calculations may be stored in a library and reused across different mix designs or bins.

In some implementations, calculations may be associated with specific tests or questions. For example, a question may prompt the user to enter the batch weight for a 3-inch sieve, and a calculation may use that input to determine the percentage retained or to compute a bin-level variable. These calculated values may then be compared to pass/fail thresholds defined in the mix design to determine compliance.

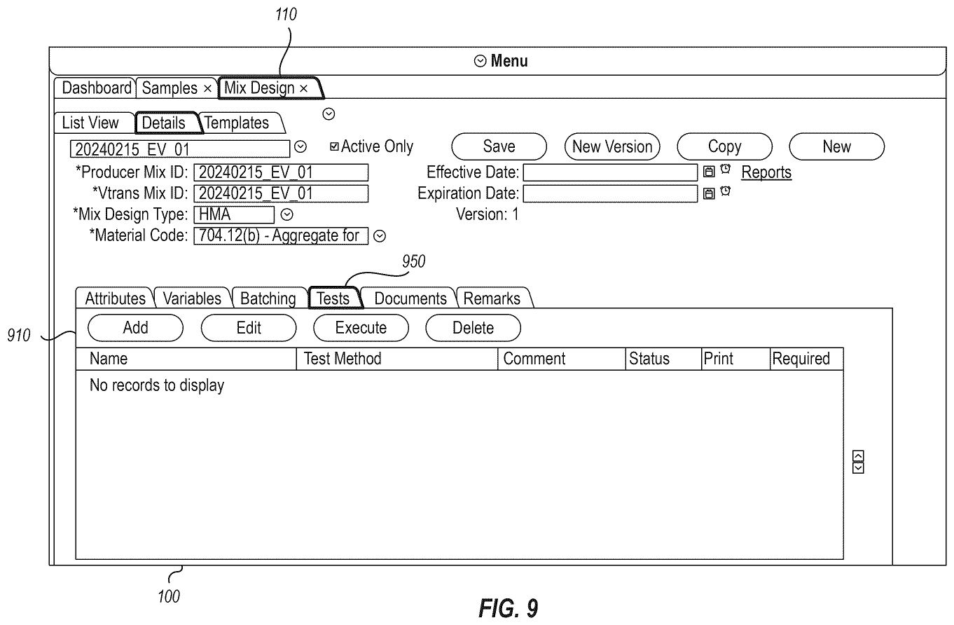

FIG. 9 illustrates a user interface 100 showing a mix design panel 110 including a tests selectable element 950 associated with a method in accordance with one or more embodiments described herein. As shown in FIG. 9, the method may include presenting, on the user interface 100, a tests subpanel 910 (or mix design test interface). The tests subpanel 910 may incorporate similar functions and/or features associated with the tests information subpanel 610 described above and may be presented upon selection by a user of a tests selectable element 950 on the user interface 100. The tests subpanel 910 may additionally or alternatively enable the execution of tests. For example, a user may add a test. The added test may be added from a previously saved or previously generated test as described above in association with the tests information subpanel 610.

The tests subpanel of the mix design panel may serve as the interface for associating previously defined test templates with a specific mix design. Upon selection of a test, the system may allow the user to customize the test for the mix design by defining specific compliance criteria. These criteria may include upper bounds, lower bounds, expected states, pass/fail thresholds for variables derived for the test, and/or others.

For example, a test may include a question prompting the user to enter the batch weight for a 3-inch sieve, and a calculation may determine the percentage retained. The user may then define a passing range (e.g., 5% to 10%) for that variable. If the sample mix input falls within the defined range, the test may return a passing result. Otherwise, the result may indicate non-compliance with the mix design.

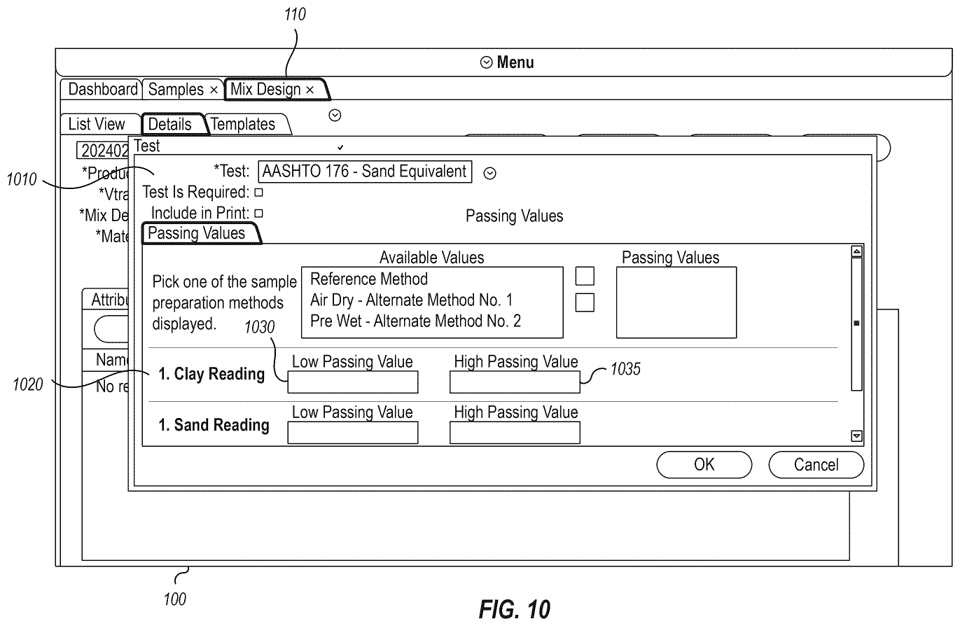

FIG. 10 illustrates a user interface 100 showing a test details subpanel 1010 associated with a method in accordance with one or more embodiments described herein. As shown in FIG. 10, the method may include presenting, on the user interface 100, a test details subpanel 1010 that may include information relating to a user-selected test. In some instances, the added test may have one or more questions 1020 (or prompts or information queries) and one or more calculations associated with each question (as described above). In the example shown in FIG. 10, the added test may have passing values, which may be a range of passing values including high passing values 1030 and low passing values 1035. The high passing values 1030 and low passing values 1035 may be input by a user. Accordingly, the method can include receiving, from a user, information corresponding to passing values for questions associated with a test to determine whether a material meets the requirements of a representation of a mix design.

The test details subpanel may allow users to define granular compliance parameters for a test associated with a mix design. These parameters may include high passing values, low passing values, expected states (e.g., true/false, present/absent), or other pass/fail criteria. The system may present input fields for each question or variable in the test, allowing the user to specify acceptable ranges or conditions.

In some implementations, the system may support conditional logic, such that the outcome of one question or calculation may influence the evaluation of another. For example, if a sample fails a binder content test, subsequent questions related to binder source may be skipped or flagged. These features allow for flexible and robust compliance testing tailored to the requirements of each mix design.

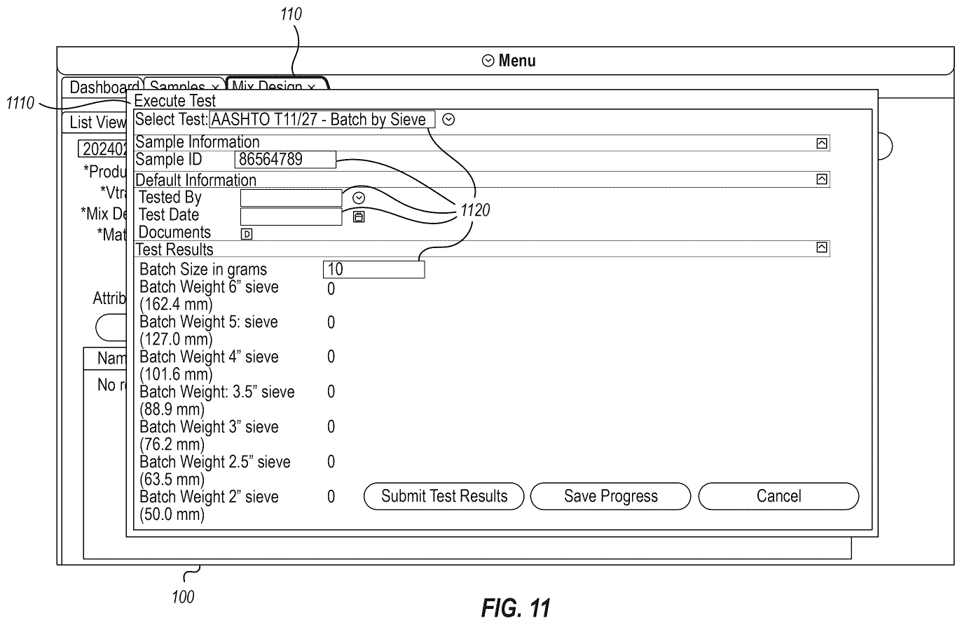

FIG. 11 illustrates a user interface 100 showing an execute test subpanel 1110 associated with a method in accordance with one or more embodiments described herein. As shown in FIG. 11, the method may include executing one or more tests associated with a mix design. Upon execution, the system may present, on the user interface 100, an execute test subpanel 1110 that includes one or more execute test user input fields 1120. These input fields 1120 may be defined by the questions previously associated with the test (e.g., via the tests information subpanel or the mix design panel), and may prompt the user to input sample mix data for evaluation.

The questions presented in the execute test subpanel 1110 may include prompts such as “Enter the batch weight for the 3-inch sieve,” “Provide the clay reading,” or “Specify the binder content.” These questions may be of various types, including short answer, multiple choice, linked sample, or calculation result, and may be configured to elicit input relevant to the composition or characteristics of a sample mix.

The system may use the responses to these questions as inputs to one or more calculations associated with the test. Each calculation may transform the user input into a variable (e.g., air voids, oil content, binder correction factor) that is indicative of a measurable property of the sample mix. These variables may then be evaluated against pass/fail criteria defined for the test, such as upper bounds, lower bounds, expected states, or threshold ranges.

For example, a calculation may determine the percentage of material retained on a specific sieve, and the system may assess whether that value falls within a predefined acceptable range (e.g., 5% to 10%). If the calculated variable satisfies the defined criteria, the system may return a passing result for that question or for the test overall. Otherwise, the system may return a failing result, indicating that the sample mix does not correspond to the mix design.

In some implementations, the test may return both an overall pass/fail result and individual pass/fail results for each question or variable. This allows users to identify specific areas of non-compliance and make targeted adjustments to the mix. As discussed in the disclosure meeting, this execution process supports real-world workflows in which users validate whether a sample mix conforms to a target mix design by inputting test data (e.g., from sieving or lab analysis) and receiving structured, automated feedback.

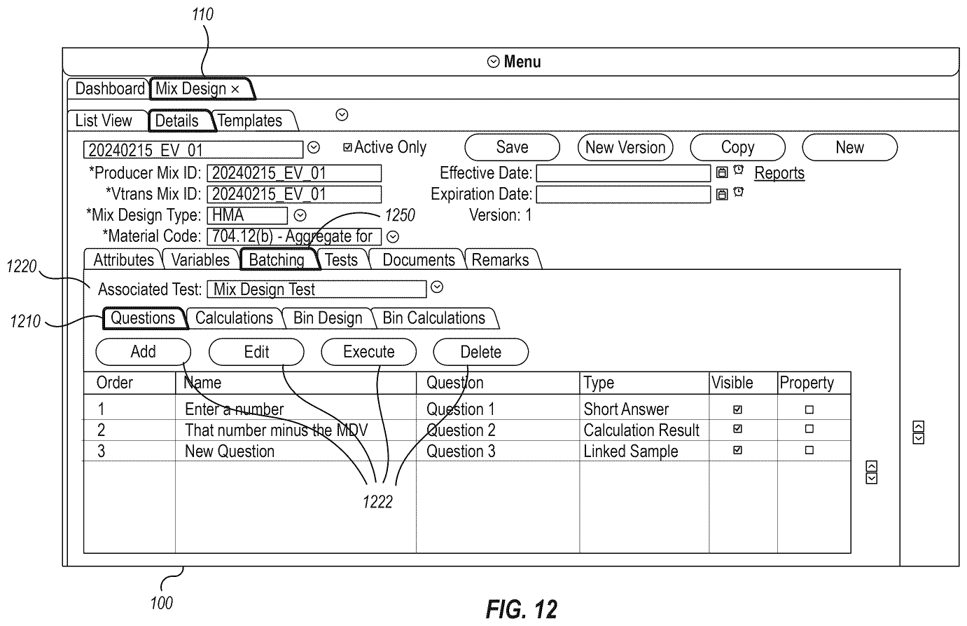

FIG. 12 illustrates a user interface 100 showing a mix design panel 110 including a batching subpanel 1220 (or a batching interface) and a batching questions subpanel 1210 associated with a method in accordance with one or more embodiments described herein. As shown in FIG. 12, the method may include, after a selection of a batching selectable element 1250, displaying, one the user interface 100 a batching subpanel 1220 that contains one or more additional panels, including a batching questions subpanel 1210, a calculations panel, a bin design subpanel, and a bin calculations panel. FIG. 12 illustrates the batching questions subpanel 1210 open, which includes selectable elements 1222. The selectable elements 1222 may include an add question element, an edit question element, a copy question element, a paste question element, and a delete question element. The batching questions subpanel 1210 may include features similar to those described hereinabove with reference to the questions subpanel 650. The questions defined via the batching questions subpanel 1210 may be applied to or associated with one or more bins defined via the bin design subpanel.

The batching interface may include a batching questions subpanel that enables a user to define one or more bin-level questions for one or more of the plurality of bins in a mix design. A bin-level question may comprise a prompt configured to elicit user input specific to a composition or characteristic of the corresponding bin. These questions may be distinct from mix-level questions in that they are tailored to the properties of individual components or bins of the mix (e.g., aggregate types, sieve fractions, or material sources).

For example, a bin-level question may prompt the user to input the batch weight for a specific sieve size (e.g., “Batch weight: 3-inch sieve (76.2 mm)”) or to indicate the moisture content of a particular aggregate bin. Other examples include: “Enter the percent retained for the 2.5-inch sieve” or “Specify the material type for Bin 4.”

In some implementations, bin-level questions may be ported from a shared pool of questions defined at the mix level or in a template, and may be refined or customized for the specific bin context. The system may allow users to associate each question with a particular bin and store the association in the structured data model representing the mix design.

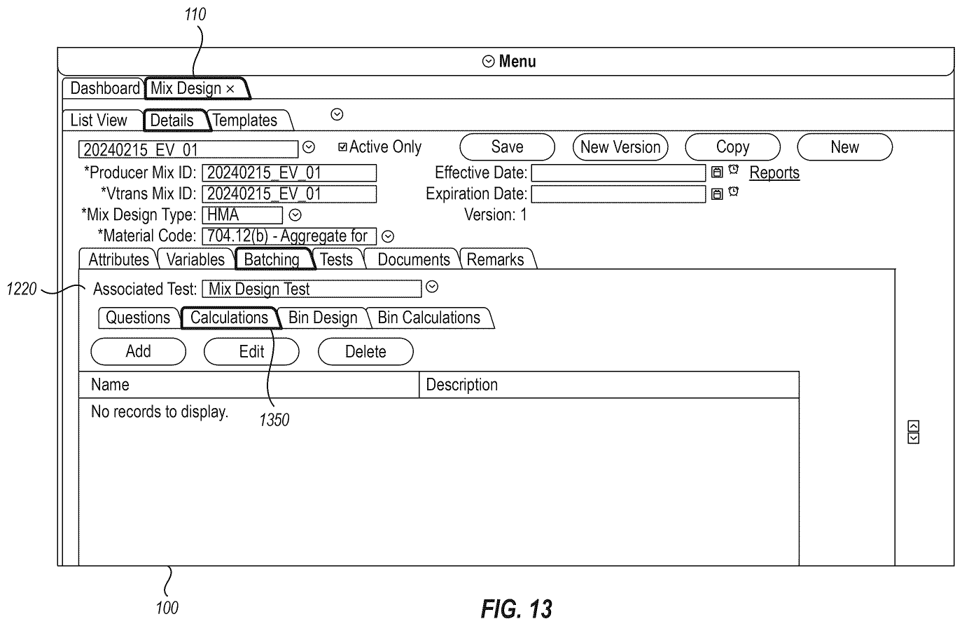

FIG. 13 illustrates a user interface 100 showing a mix design panel 110 including a batching subpanel 1220 (or batching interface) and a calculations subpanel 1350 associated with a method in accordance with one or more embodiments described herein. The calculations subpanel 1350 may enable similar functionality as heretofore described with reference to the add calculation subpanel 810 by generating calculations and associating the calculations with questions and/or mix design variables. The calculations defined via the calculations subpanel 1350 may be applied to or associated with one or more bins defined via the bin design subpanel.

The batching calculations subpanel (e.g., part of the batching interface) may allow users to define calculations specific to individual bins of a mix design. These bin-level calculations may operate on inputs such as batch weights or material properties for a given sieve size, and may produce bin-level variables that are used to assess whether the bin satisfies the requirements of the mix design as indicate din the mix design representation. Bin-level calculations may be used to derive measurable properties of the bin, such as percent passing, average retained weight, or adjusted binder content.

For example, a bin-level calculation may compute the percentage of material retained on a specific sieve, or determine the average weight across multiple bins, or determine the corrected moisture content for a bin based on environmental factors. These calculations may be linked to bin-level questions and executed during runtime to determine whether the sample mix corresponds to the target mix design. The system may allow users to port calculations from mix-level to bin-level contexts, or to define new calculations tailored to specific bin configurations. The bin-level calculations may be defined using any desired syntax and may reference one or more bin-level questions or constants.

As with questions, bin-level calculations may be ported from a shared pool or template and refined for the specific bin. The system may store the association between each calculation and its corresponding bin in the structured data model, enabling execution of the mix design representation with bin-specific logic.

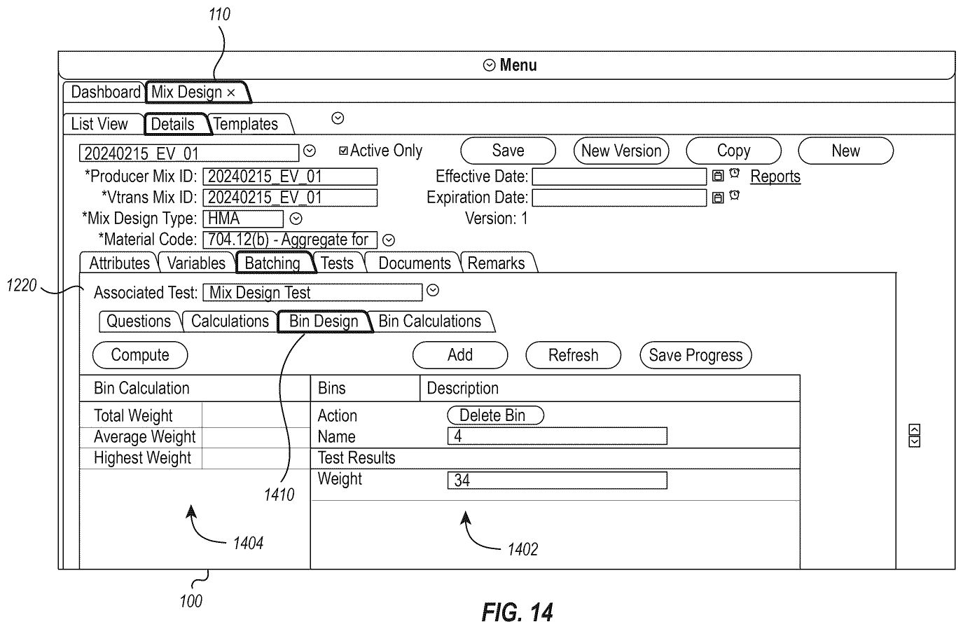

FIG. 14 illustrates a user interface 100 showing a mix design panel 110 including a batching subpanel 1220 and a bin design subpanel 1410 associated with a method in accordance with one or more embodiments described herein. As shown in FIG. 14, the method may include presenting, on the user interface 100, a batching subpanel 1220 that includes a bin design subpanel 1410. Through the bin design subpanel 1410, the user may generate a bin definition, and a defined bin may use the questions generated via the batching questions subpanel 1210, the calculations generated via the calculations subpanel 1350, and/or pre-generated or customized tests. In the example shown in FIG. 14, a single bin 1402 (with the name “4”) is included in the mix design, though any quantity or combination of bins may be implemented. Bin 1402 (and/or other bins) may be added via selectable elements shown under the bin design subpanel 1410 for adding a new bin (labeled “Add”). Bins may also be deleted by provided functionality (e.g., a selectable element labeled “Delete Bin”, which may be illustrated for each generated bin). In the example shown in FIG. 14, the bin 1402 shows a weight of 34, which may comprise a value determined via execution of a test and/or one or more calculations (defined via calculations subpanel 1350) using inputs defined via response to one or more questions (defined via batching questions subpanel 1210). Similar calculations and/or results may be determined for any quantity of bins of a mix design. Additionally or alternatively, the weight may be an input weight by a user of the weight of material in a bin associated with a sieve performed by the user that corresponds to the Bin 1402.

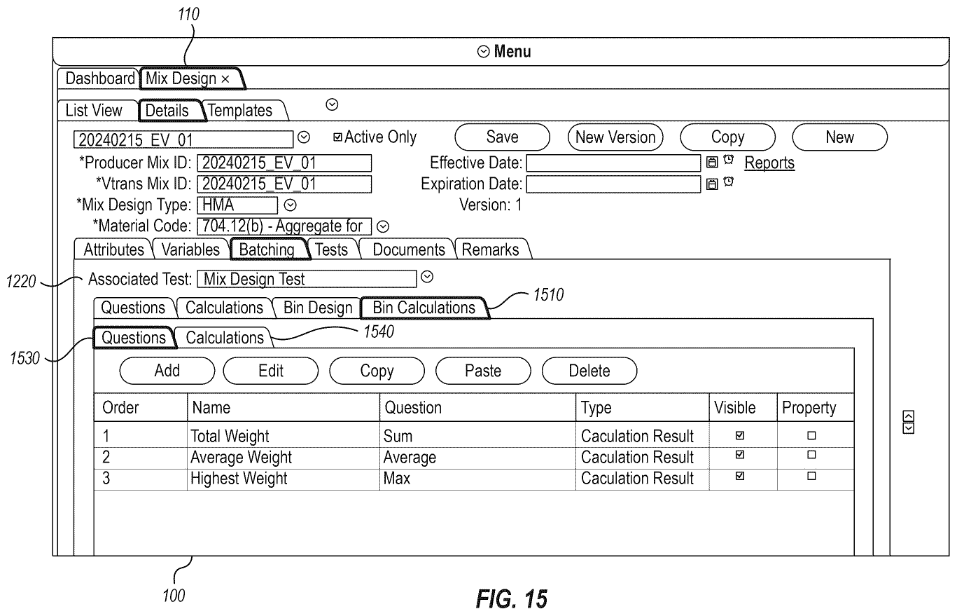

Additional bin calculations may be performed based on results or outputs associated with multiple bins of a mix design. For instance, FIG. 14 illustrates a bin calculation region 1404 including example values calculated based on outputs or test results of multiple bins (e.g., “Total Weight”, “Average Weight”, “Highest Weight”, etc.). The bin calculations may be defined via a bin calculations subpanel 1510, as illustrated in FIG. 15. In the example shown in FIG. 15, the bin calculations subpanel 1510 includes its own questions subpanel 1530 and calculations subpanel 1540 that may be used to define the manner in which results from multiple bins may be combined in the bin calculation region 1404 (shown in FIG. 14). The questions and/or calculations used for the bin calculation region 1404 may be selected from or modified based on existing questions and/or calculations previously generated (as described above).

By combining multiple bin definitions, a user may generate or modify a representation of a mix design. Accordingly, the method may include generating one or more bin definitions and combining one or more bin definitions to construct the representation of the mix design. Generating a bin definition may thus include generating questions regarding the bin in the mix design; generating calculations for the bin in the mix design; and determining a bin definition based on the questions and calculations. In some instances, a report may be generated based on one or more question answers and/or execution of one or more tests or calculations associated with one or more bins of a mix design.

The bin design subpanel may serve as a central interface for defining and managing the plurality of bins that make up a mix design. Each bin may correspond to a portion of the overall composition of the mix (e.g., 30% of Bin 1, 25% of Bin 2, etc.). The system may allow users to associate each bin with one or more bin-level questions and/or bin-level calculations, as defined via the batching interface.

These associations may be stored in the structured data model representing the mix design, enabling the system to execute bin-specific logic during testing or validation. For example, when a sample mix is tested, the system may present the bin-level questions for each bin, receive user input, perform the associated calculations, and determine whether the bin-level variables satisfy the criteria defined for the mix design. This modular approach may allow for granular control and validation of each component of the mix.

In some embodiments, after a user has defined one or more attributes, questions, calculations, variables, and/or tests for a mix design via the interfaces described with reference to FIGS. 1 through 15, the system may construct a representation of the mix design. This representation may comprise a structured data model that encodes the logical relationships and evaluation criteria defined by the user. The structured data model may be configured to be executable by one or more systems to determine whether a sample mix corresponds to the mix design. Additionally, the representation of the mix design may be used to guide the formation of a mix that attempts to correspond to the mix design represented by the structured data model. For example, the attributes defined in the representation (e.g., binder grade, sieve percentages, admixture type) may act as a recipe that enables reproduction of the mix design in a real-world setting. A user or system may reference these attributes to configure mixing equipment, select materials, and proportion components to produce a mix intended to match the defined design.

Execution of the representation of the mix design may include presenting a sample input interface comprising the one or more questions defined for the mix design. These questions may be presented as prompts on a graphical user interface and may correspond to the questions created and stored during mix design setup, such as those described with reference to FIGS. 6, 7, and 11. The sample input interface may include user input elements such as text fields, dropdown menus, buttons, binary selectors (e.g., checkboxes, toggles), sliders, or other modalities for receiving user responses to the questions. For example, the interface may prompt the user to enter batch weights for specific sieve sizes, provide readings for material properties such as clay or moisture content, or select values from predefined lists.

The answers to these questions may be based on real-world physical tests performed on one or more sample mixes. These sample mixes may be obtained from a mix formed using the attributes of the representation of the mix design, or from another mix intended to be evaluated against the mix design. Physical tests may include, for example, a crushing test to determine compressive strength, a sieve analysis to determine aggregate gradation, a moisture content test to assess water absorption, and/or others. The resulting test data (e.g., pounds of force sustained before failure, percent retained on each sieve, measured moisture percentage, etc.) may be input into the sample input interface as responses to the questions defined in the mix design representation.

Upon receiving the sample mix input via the sample input interface, the system may use the input to determine one or more sample mix attributes, such as binder grade or sieve percentage, based on the responses. The system may additionally or alternatively perform one or more calculations defined for the mix design using the sample mix input. These calculations may transform the input into derived values or variables, such as air voids, oil content, or binder correction factor, which are stored as sample mix variables. The system may then evaluate whether the sample mix corresponds to the mix design by testing whether the sample mix variables satisfy the compliance criteria defined in the mix design tests. These criteria may include upper bounds, lower bounds, expected states, or pass/fail thresholds, and may be evaluated using logic defined in the structured data model.

In addition to evaluating mix-level components, the system may also present, via the sample input interface, the one or more bin-level questions for each bin of the plurality of bins defined in the mix design. These bin-level questions may be tailored to the composition or characteristics of individual bins and may include prompts such as “Enter the batch weight for Bin 2” or “Specify the material type for Bin 4.” The sample input interface may include input fields and display elements similar to those described with reference to FIG. 11, allowing the user to provide bin-specific data in a structured and intuitive manner. User input providing responses to bin-level questions may be determined based on results obtained from performing sieving operations on a sample mix. For example, a technician may pass the sample mix through a series of sieves of decreasing mesh size to separate the mix into discrete bins, and then measure the weight or percentage of material retained on each sieve (and/or other attributes/characteristics associated with each sieve). These and/or other measurements may be used to populate responses to bin-level questions such as batch weight or percent retained for a given bin.

After receiving bin-level sample mix input responsive to the bin-level questions, the system may perform the one or more bin-level calculations associated with each bin. These calculations may determine bin-level variables such as percent retained, average weight, or adjusted binder content. The system may then evaluate whether the sample mix corresponds to the mix design by testing whether the bin-level variables satisfy one or more bin-level tests associated with the mix design. These tests may include criteria specific to each bin and may be defined using ranges, thresholds, or logical conditions. The results of the bin-level tests may be aggregated with mix-level results to provide a comprehensive assessment of whether the sample mix conforms to the defined mix design.

The sample input interface used during execution of the representation of the mix design may be part of the same software application used to construct the mix design and may include features consistent with those shown in FIGS. 1 through 15. The interface may be implemented in a downloadable desktop application, a mobile app, or a web-based platform, and may support dynamic rendering of questions, real-time calculation of variables, and automated evaluation of test results. In some implementations, the interface may also support report generation, data export, and integration with external systems for compliance tracking or project management.

The structured data model representing the mix design may be embodied as an executable data object, which may include, for example, a JSON or XML object, a compiled or interpreted script, a database record, or a containerized module. The executable representation may be run using a software application that interprets the data model and presents the corresponding user interface elements for execution. These elements may include graphical display panels, input fields, dropdown menus, prompts, calculation previews, pass/fail indicators, and summary reports. The representation may be stored locally, in cloud-based storage, or in centralized databases, and may be transmitted between systems or users to facilitate collaborative workflows such as proposal, review, and approval of mix designs.

Although the examples described herein have focused, in at least some respects, on the use of direct user input to provide responses to questions associated with a representation of a mix design (whether mix-level or bin-level), other modalities may be used. For instance, answers to questions may be obtained by uploading, receiving, processing, or otherwise acquiring information from an input file formatted in a structured or tabular manner (e.g., CSV, XLSX, JSON, or other machine-readable formats). Such a file may include test data generated by performing real-world physical tests on a sample mix. For example, a technician may perform a sieve analysis, and the percent retained on each sieve size, along with moisture content, binder content, compressive strength values, and/or other data may be recorded in a tabular dataset (automatically or manually). The system executing the structured data model (i.e., the representation of the mix design) may process the uploaded file to extract the relevant values and automatically populate answers to the corresponding mix-level and bin-level questions. This approach may facilitate efficient batch processing of test results, reduce manual data entry, and support integration with laboratory information management systems or other external data sources.

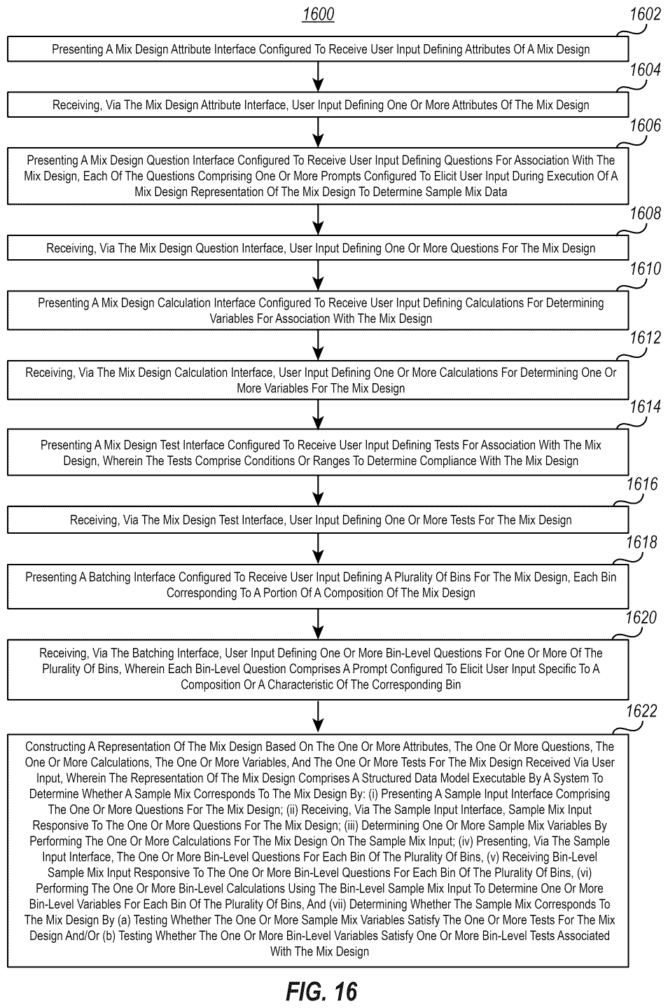

FIG. 16 illustrates a flow diagram 1600 depicting a method for constructing a representation of a mix design in accordance with one or more embodiments described herein. It will be appreciated that not all acts shown in flow diagram 1600 need be performed in all embodiments, and that the order of the acts may be varied unless explicitly stated otherwise or unless the performance of one act is dependent on the completion of another. The acts represented in flow diagram 1600 may be performed via one or more components of a system 1700 (e.g., one or more processors 1702 executing instructions stored on storage 1704).

Act 1602 of flow diagram 1600 includes presenting a mix design attribute interface configured to receive user input defining attributes of a mix design (e.g., attributes subpanel 220). The mix design attribute interface may be presented via a graphical user interface and may include input fields, dropdown menus, and selection elements for defining characteristics of the mix design. Attributes may include, for example, binder grade, admixture type, sieve percentages, or other physical or chemical properties relevant to the mix. In some implementations, the interface may allow users to select attributes from a predefined list or create custom attributes for a particular mix design.

Act 1604 includes receiving, via the mix design attribute interface, user input defining one or more attributes of the mix design. The system 1700 may store the received attributes in association with the mix design and may use the attributes as part of a structured data model that defines the mix design. These attributes may later be used to guide reproduction of the mix (e.g., by configuring mixing equipment or selecting materials) and may also be used as reference points during testing to determine whether a sample mix corresponds to the mix design.

Act 1606 includes presenting a mix design question interface configured to receive user input defining questions for association with the mix design (e.g., tests information subpanel 610, add question subpanel 710). Each question may comprise one or more prompts configured to elicit user input during execution of the mix design representation to determine sample mix data. Questions may include prompts such as “Enter the batch weight for the 3-inch sieve,” “Provide the clay reading,” or “Specify the binder content.” The interface may support various question types, including short answer, multiple choice, linked sample, and calculation result.

Act 1608 includes receiving, via the mix design question interface, user input defining one or more questions for the mix design. The system 1700 may store the questions in a question library and associate them with the mix design. These questions may later be presented during execution of the mix design representation to collect sample mix data for evaluation.

Act 1610 includes presenting a mix design calculation interface configured to receive user input defining calculations for determining variables for association with the mix design (e.g., add calculation subpanel 810, calculations subpanel 1350). The calculation interface may allow users to define formulas or expressions that transform responses to questions into derived values. Calculations may be defined using spreadsheet-style syntax and may reference one or more questions, constants, or previously defined variables.

Act 1612 includes receiving, via the mix design calculation interface, user input defining one or more calculations for determining one or more variables for the mix design. Variables may include measurable properties of the mix such as air voids, oil content, or binder correction factor. The system 1700 may store the calculations and associate them with the mix design, enabling automated evaluation of sample mix data during execution.

Act 1614 includes presenting a mix design test interface configured to receive user input defining tests for association with the mix design (e.g., tests subpanel 910, test details subpanel 1010). The tests may comprise conditions or ranges to determine compliance with the mix design. For example, a test may include a passing range for binder content (e.g., 5% to 7%) or a threshold for compressive strength (e.g., ≥4,000 psi). The interface may allow users to define pass/fail criteria, expected states, and other evaluation parameters.

Act 1616 includes receiving, via the mix design test interface, user input defining one or more tests for the mix design. The system 1700 may store the tests and associate them with the mix design, enabling structured evaluation of sample mix data during execution.

Act 1618 includes presenting a batching interface configured to receive user input defining a plurality of bins for the mix design (e.g., bin design subpanel 1410). Each bin may correspond to a portion of a composition of the mix design. For example, a mix design may include 30% of Bin 1, 25% of Bin 2, and so on. The batching interface may allow users to define bin compositions, associate bins with attributes, and configure bin-level evaluation criteria.

Act 1620 includes receiving, via the batching interface, user input defining one or more bin-level questions for one or more of the plurality of bins (e.g., batching questions subpanel 1210). Each bin-level question may comprise a prompt configured to elicit user input specific to a composition or a characteristic of the corresponding bin. For example, a bin-level question may prompt the user to enter the batch weight for Bin 3 or specify the material type for Bin 4. These questions may be ported from mix-level templates or defined specifically for the bin context.

Act 1622 includes constructing a representation of the mix design based on the one or more attributes, the one or more questions, the one or more calculations, the one or more variables, and the one or more tests for the mix design received via user input. The representation of the mix design may comprise a structured data model executable by a system (e.g., system 1700) to determine whether a sample mix corresponds to the mix design. Execution of the structured data model may include presenting a sample input interface comprising the one or more questions for the mix design (e.g., execute test subpanel 1110), receiving, via the sample input interface, sample mix input responsive to the one or more questions for the mix design (e.g., based on real-world physical tests such as crushing, sieving, or moisture analysis), determining one or more sample mix variables by performing the one or more calculations for the mix design on the sample mix input, presenting, via the sample input interface, the one or more bin-level questions for each bin of the plurality of bins, receiving bin-level sample mix input responsive to the one or more bin-level questions for each bin of the plurality of bins (e.g., based on sieving operations and weight measurements), performing the one or more bin-level calculations using the bin-level sample mix input to determine one or more bin-level variables for each bin of the plurality of bins, and determining whether the sample mix corresponds to the mix design by testing whether the one or more sample mix variables satisfy the one or more tests for the mix design and/or testing whether the one or more bin-level variables satisfy one or more bin-level tests associated with the mix design.

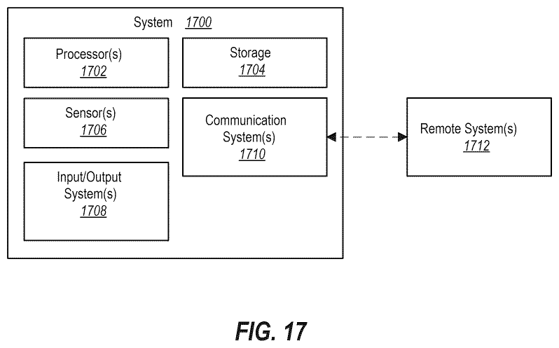

FIG. 17 illustrates various example components of a system 1700. For example, FIG. 17 illustrates an implementation in which the system includes processor(s) 1702, storage 1704, sensor(s) 1706, I/O system(s) 1708, and communication system(s) 1710. Although FIG. 17 illustrates a system 1700 as including particular components, one will appreciate, in view of the present disclosure, that a system 1700 may comprise any number of additional or alternative components.

The processor(s) 1702 may comprise one or more sets of electronic circuitries that include any number of logic units, registers, and/or control units to facilitate the execution of computer-readable instructions (e.g., instructions that form a computer program). Such computer-readable instructions may be stored within storage 1704. The storage 1704 may comprise computer-readable recording media and may be volatile, non-volatile, or some combination thereof. Furthermore, storage 1704 may comprise local storage, remote storage (e.g., accessible via communication system(s) 1710 or otherwise), or some combination thereof. Additional details related to processors (e.g., processor(s) 1702) and computer storage media (e.g., storage 1704) will be provided hereinafter.

In some implementations, the processor(s) 1702 may comprise or be configurable to execute any combination of software and/or hardware components that are operable to facilitate processing using machine learning models or other artificial intelligence-based structures/architectures. For example, processor(s) 1702 may comprise and/or utilize hardware components or computer-executable instructions operable to carry out function blocks and/or processing layers configured in the form of, by way of non-limiting example, single-layer neural networks, feed forward neural networks, radial basis function networks, deep feed-forward networks, recurrent neural networks, long-short term memory (LSTM) networks, gated recurrent units, autoencoder neural networks, variational autoencoders, denoising autoencoders, sparse autoencoders, Markov chains, Hopfield neural networks, Boltzmann machine networks, restricted Boltzmann machine networks, deep belief networks, deep convolutional networks (or convolutional neural networks), deconvolutional neural networks, deep convolutional inverse graphics networks, generative adversarial networks, liquid state machines, extreme learning machines, echo state networks, deep residual networks, Kohonen networks, support vector machines, neural Turing machines, and/or others.

As will be described in more detail, the processor(s) 1702 may be configured to execute instructions stored within storage 1704 to perform certain actions. The actions may rely at least in part on data stored on storage 1704 in a volatile or non-volatile manner. In some instances, the actions may rely at least in part on communication system(s) 1710 for receiving data from remote system(s) 1712, which may include, for example, separate systems or computing devices, sensors, and/or others. The communications system(s) 1710 may comprise any combination of software or hardware components that are operable to facilitate communication between on-system components/devices and/or with off-system components/devices. For example, the communications system(s) 1710 may comprise ports, buses, or other physical connection apparatuses for communicating with other devices/components. Additionally, or alternatively, the communications system(s) 1710 may comprise systems/components operable to communicate wirelessly with external systems and/or devices through any suitable communication channel(s), such as, by way of non-limiting example, Bluetooth, ultra-wideband, WLAN, infrared communication, and/or others.

FIG. 17 illustrates that a system 1700 may comprise or be in communication with sensor(s) 1706. Sensor(s) 1706 may comprise any device for capturing or measuring data representative of perceivable phenomena. By way of non-limiting example, the sensor(s) 1706 may comprise one or more image sensors, microphones, thermometers, barometers, magnetometers, accelerometers, gyroscopes, and/or others.

Furthermore, FIG. 17 illustrates that a system 1700 may comprise or be in communication with I/O system(s) 1708. I/O system(s) 1708 may include any type of input or output device such as, by way of non-limiting example, a touch screen, a mouse, a keyboard, a controller, and/or others, without limitation. For example, the I/O system(s) 1708 may include a display system that may comprise any number of display panels or screens, projectors, optics, laser scanning display assemblies, and/or other components.

The present invention may comprise or utilize a special-purpose or general-purpose computer system that includes computer hardware, such as, for example, one or more processing modules and system memory, as discussed in greater detail below. The scope of the present invention also includes physical and other computer-readable media for carrying or storing computer-executable instructions and/or data structures. Such computer-readable media can be any available media that can be accessed by a general-purpose or special-purpose computer system. Computer-readable media that store computer-executable instructions and/or data structures are computer storage media. Computer-readable media that carry computer-executable instructions and/or data structures are transmission media. Thus, by way of example, and not limitation, the invention can comprise at least two distinctly different kinds of computer-readable media: computer storage media and transmission media.

Computer storage media are physical storage media that store computer-executable instructions and/or data structures. Physical storage media include computer hardware, such as RAM, ROM, EEPROM, solid state drives (“SSDs”), flash memory, phase-change memory (“PCM”), optical disk storage, magnetic disk storage or other magnetic storage devices, or any other hardware storage device(s) which can be used to store program code in the form of computer-executable instructions or data structures, which can be accessed and executed by a general-purpose or special-purpose computer system to implement the disclosed functionality of the invention.

Transmission media can include a network and/or data links which can be used to carry program code in the form of computer-executable instructions or data structures, and which can be accessed by a general-purpose or special-purpose computer system. A “network” is defined as one or more data links that enable the transport of electronic data between computer systems and/or modules and/or other electronic devices. When information is transferred or provided over a network or another communications connection (either hardwired, wireless, or a combination of hardwired or wireless) to a computer system, the computer system may view the connection as transmission media. Combinations of the above should also be included within the scope of computer-readable media.

Further, upon reaching various computer system components, program code in the form of computer-executable instructions or data structures can be transferred automatically from transmission media to computer storage media (or vice versa). For example, computer-executable instructions or data structures received over a network or data link can be buffered in RAM within a network interface module (e.g., a “NIC”), and then eventually transferred to computer system RAM and/or to less volatile computer storage media at a computer system. Thus, it should be understood that computer storage media can be included in computer system components that also (or even primarily) utilize transmission media.

Computer-executable instructions comprise, for example, instructions and data which, when executed at one or more processing modules, cause a general-purpose computer system, special-purpose computer system, or special-purpose processing device to perform a certain function or group of functions. Computer-executable instructions may be, for example, binaries, intermediate format instructions such as assembly language, or even source code.

Those skilled in the art will appreciate that the invention may be practiced in network computing environments with many types of computer system configurations, including, personal computers, desktop computers, laptop computers, message processing modules, hand-held devices, multi-processing module systems, microprocessing module-based or programmable consumer electronics, network PCs, minicomputers, mainframe computers, mobile telephones, PDAs, tablets, pagers, routers, switches, and the like. The invention may also be practiced in distributed system environments where local and remote computer systems, which are linked (either by hardwired data links, wireless data links, or by a combination of hardwired and wireless data links) through a network, both perform tasks. As such, in a distributed system environment, a computer system may include a plurality of constituent computer systems. In a distributed system environment, program modules may be located in both local and remote memory storage devices.

Those skilled in the art will also appreciate that the invention may be practiced in a cloud-computing environment. Cloud computing environments may be distributed, although this is not required. When distributed, cloud computing environments may be distributed internationally within an organization and/or have components possessed across multiple organizations. In this description and the following claims, “cloud computing” is defined as a model for enabling on-demand network access to a shared pool of configurable computing resources (e.g., networks, servers, storage, applications, and services). The definition of “cloud computing” is not limited to any of the other numerous advantages that can be obtained from such a model when properly deployed.

A cloud-computing model can be composed of various characteristics, such as on-demand self-service, broad network access, resource pooling, rapid elasticity, measured service, and so forth. A cloud-computing model may also come in the form of various service models such as, for example, Software as a Service (“SaaS”), Platform as a Service (“PaaS”), and Infrastructure as a Service (“IaaS”). The cloud-computing model may also be deployed using different deployment models such as private cloud, community cloud, public cloud, hybrid cloud, and so forth.

A cloud-computing environment, or cloud-computing platform, may comprise a system that includes one or more hosts that are each capable of running one or more virtual machines. During operation, virtual machines emulate an operational computing system, supporting an operating system and perhaps one or more other applications as well. Each host may include a hypervisor that emulates virtual resources for the virtual machines using physical resources that are abstracted from view of the virtual machines. The hypervisor also provides proper isolation between the virtual machines. Thus, from the perspective of any given virtual machine, the hypervisor provides the illusion that the virtual machine is interfacing with a physical resource, even though the virtual machine only interfaces with the appearance (e.g., a virtual resource) of a physical resource. Examples of physical resources including processing capacity, memory, disk space, network bandwidth, media drives, and so forth.

Although the subject matter has been described in language specific to structural features and/or methodological acts, it is to be understood that the subject matter defined in the appended claims is not necessarily limited to the described features or acts described above, or the order of the acts described above. Rather, the described features and acts are disclosed as example forms of implementing the claims.

1. A system for constructing a representation of a mix design, the system comprising:
one or more processors; and
one or more computer-readable recording media that store instructions that are executable such that the system is configurable to:
present a mix design attribute interface configured to receive user input defining attributes of a mix design;
receive, via the mix design attribute interface, user input defining one or more attributes of the mix design;
present a mix design question interface configured to receive user input defining questions for association with the mix design, each of the questions comprising one or more prompts configured to elicit user input during execution of a mix design representation of the mix design to determine sample mix data;
receive, via the mix design question interface, user input defining one or more questions for the mix design;
present a mix design calculation interface configured to receive user input defining calculations for determining variables for association with the mix design;
receive, via the mix design calculation interface, user input defining one or more calculations for determining one or more variables for the mix design;
present a mix design test interface configured to receive user input defining tests for association with the mix design, wherein the tests comprise conditions or ranges to determine compliance with the mix design;
receive, via the mix design test interface, user input defining one or more tests for the mix design; and
construct a representation of the mix design based on the one or more attributes, the one or more questions, the one or more calculations, the one or more variables, and the one or more tests for the mix design received via user input, wherein the representation of the mix design comprises a structured data model executable by one or more system to determine whether a sample mix corresponds to the mix design by:
presenting a sample input interface comprising the one or more questions for the mix design;
receiving, via the sample input interface, sample mix input responsive to the one or more questions for the mix design;
determining one or more sample mix variables by performing the one or more calculations for the mix design on the sample mix input; and
determining whether the sample mix corresponds to the mix design by testing whether the one or more sample mix variables satisfy the one or more tests for the mix design.

2. The system of claim 1, wherein determining whether the sample mix corresponds to the mix design further comprises determining whether one or more sample mix attributes obtained via the sample input interface correspond to the one or more attributes of the mix design.

3. The system of claim 1, wherein the one or more attributes of the mix design comprise one or more of material type, sieve percentage, or binder grade.

4. The system of claim 1, wherein the one or more variables comprise one or more of air voids, oil content, or binder correction factor.

5. The system of claim 1, wherein the one or more tests comprise one or more of upper bounds, lower bounds, expected states, or pass/fail criteria.

6. The system of claim 1, wherein the instructions are executable by the one or more processors such that the system is configurable to:
present a batching interface configured to receive user input defining a plurality of bins for the mix design, each bin corresponding to a portion of a composition of the mix design.

7. The system of claim 6, wherein the instructions are executable by the one or more processors such that the system is configurable to:
receive, via the batching interface, user input defining one or more bin-level questions for one or more of the plurality of bins, wherein each bin-level question comprises a prompt configured to elicit user input specific to a composition or a characteristic of the corresponding bin.

8. The system of claim 7, wherein the instructions are executable by the one or more processors such that the system is configurable to:
receive, via the batching interface, user input defining one or more bin-level calculations for one or more of the plurality of bins, wherein each bin-level calculation is configured to determine one or more bin-level variables based on one or more responses to the one or more bin-level questions.

9. The system of claim 8, wherein constructing the representation of the mix design further comprises:
associating the one or more bin-level questions and the one or more bin-level calculations with the corresponding bin of the plurality of bins in the structured data model.

10. The system of claim 9, wherein execution of the structured data model to determine whether the sample mix corresponds to the mix design further comprises:
presenting, via the sample input interface, the one or more bin-level questions for each bin of the plurality of bins;
receiving bin-level sample mix input responsive to the one or more bin-level questions for each bin of the plurality of bins;
performing the one or more bin-level calculations using the bin-level sample mix input to determine one or more bin-level variables for each bin of the plurality of bins; and
determining whether the sample mix corresponds to the mix design by testing whether the one or more bin-level variables satisfy one or more bin-level tests associated with the mix design.

11. A method for constructing a representation of a mix design, the method comprising:
presenting a mix design attribute interface configured to receive user input defining attributes of a mix design;
receiving, via the mix design attribute interface, user input defining one or more attributes of the mix design;
presenting a mix design question interface configured to receive user input defining questions for association with the mix design, each of the questions comprising one or more prompts configured to elicit user input during execution of a mix design representation of the mix design to determine sample mix data;
receiving, via the mix design question interface, user input defining one or more questions for the mix design;
presenting a mix design calculation interface configured to receive user input defining calculations for determining variables for association with the mix design;
receiving, via the mix design calculation interface, user input defining one or more calculations for determining one or more variables for the mix design;
presenting a mix design test interface configured to receive user input defining tests for association with the mix design, wherein the tests comprise conditions or ranges to determine compliance with the mix design;
receiving, via the mix design test interface, user input defining one or more tests for the mix design; and
constructing a representation of the mix design based on the one or more attributes, the one or more questions, the one or more calculations, the one or more variables, and the one or more tests for the mix design received via user input, wherein the representation of the mix design comprises a structured data model executable by a system to determine whether a sample mix corresponds to the mix design by:
presenting a sample input interface comprising the one or more questions for the mix design;
receiving, via the sample input interface, sample mix input responsive to the one or more questions for the mix design;
determining one or more sample mix variables by performing the one or more calculations for the mix design on the sample mix input; and
determining whether the sample mix corresponds to the mix design by testing whether the one or more sample mix variables satisfy the one or more tests for the mix design.

12. The method of claim 11, wherein determining whether the sample mix corresponds to the mix design further comprises determining whether one or more sample mix attributes obtained via the sample input interface correspond to the one or more attributes of the mix design.

13. The method of claim 11, wherein the one or more attributes of the mix design comprise one or more of material type, sieve percentage, or binder grade.

14. The method of claim 11, wherein the one or more variables comprise one or more of air voids, oil content, or binder correction factor.

15. The method of claim 11, wherein the one or more tests comprise one or more of upper bounds, lower bounds, expected states, or pass/fail criteria.

16. The method of claim 11, further comprising:
presenting a batching interface configured to receive user input defining a plurality of bins for the mix design, each bin corresponding to a portion of a composition of the mix design.

17. The method of claim 16, further comprising:
receiving, via the batching interface, user input defining one or more bin-level questions for one or more of the plurality of bins, wherein each bin-level question comprises a prompt configured to elicit user input specific to a composition or a characteristic of the corresponding bin.

18. The method of claim 17, further comprising:
receiving, via the batching interface, user input defining one or more bin-level calculations for one or more of the plurality of bins, wherein each bin-level calculation is configured to determine one or more bin-level variables based on one or more responses to the one or more bin-level questions.

19. The method of claim 18, wherein execution of the structured data model to determine whether the sample mix corresponds to the mix design further comprises:
presenting, via the sample input interface, the one or more bin-level questions for each bin of the plurality of bins;
receiving bin-level sample mix input responsive to the one or more bin-level questions for each bin of the plurality of bins;
performing the one or more bin-level calculations using the bin-level sample mix input to determine one or more bin-level variables for each bin of the plurality of bins; and
determining whether the sample mix corresponds to the mix design by testing whether the one or more bin-level variables satisfy one or more bin-level tests associated with the mix design.

20. One or more computer-readable recording media that store instructions that are executable by one or more processors of a system such that the system is configurable to:
present a mix design attribute interface configured to receive user input defining attributes of a mix design;
receive, via the mix design attribute interface, user input defining one or more attributes of the mix design;
present a mix design question interface configured to receive user input defining questions for association with the mix design, each of the questions comprising one or more prompts configured to elicit user input during execution of a mix design representation of the mix design to determine sample mix data;
receive, via the mix design question interface, user input defining one or more questions for the mix design;
present a mix design calculation interface configured to receive user input defining calculations for determining variables for association with the mix design;
receive, via the mix design calculation interface, user input defining one or more calculations for determining one or more variables for the mix design;
present a mix design test interface configured to receive user input defining tests for association with the mix design, wherein the tests comprise conditions or ranges to determine compliance with the mix design;
receive, via the mix design test interface, user input defining one or more tests for the mix design; and
construct a representation of the mix design based on the one or more attributes, the one or more questions, the one or more calculations, the one or more variables, and the one or more tests for the mix design received via user input, wherein the representation of the mix design comprises a structured data model executable by one or more system to determine whether a sample mix corresponds to the mix design by:
presenting a sample input interface comprising the one or more questions for the mix design;
receiving, via the sample input interface, sample mix input responsive to the one or more questions for the mix design;
determining one or more sample mix attributes based on the sample mix input;
determining one or more sample mix variables by performing the one or more calculations for the mix design on the sample mix input; and
determining whether the sample mix corresponds to the mix design by testing whether the one or more sample mix variables satisfy the one or more tests for the mix design.
